(19) United States
(12) Patent Application Publication
(10) Pub. No.: US 2016/0104810 A1
(43) Pub. Date: Apr. 14, 2016

(54) SOLAR CELL MODULE AND METHOD FOR PRODUCING SAME

(71) Applicant: KANEKA CORPORATION, Osaka (JP)

(72) Inventor: Daisuke Adachi, Kusatsu-shi, Shiga (JP)

(21) Appl. No.: 14/890,881

(22) PCT Filed: Apr. 21, 2014
(86) PCT No.: PCT/JP2014/061165

§ 371 Date: Nov. 12, 2015

(30) Foreign Application Priority Data
May 13, 2013 (JP) 2013-101334

(51) Int. Cl. H01L 31/05; H01L 31/18; H01L 31/0224

(52) U.S. Cl. CPC H01L 31/0508; H01L 31/022433; H01L 31/18

(57) ABSTRACT

A solar cell module having low resistance loss between a collector electrode and a connection wiring line, and a method for producing the solar cell module. A solar cell includes a finger electrode portion extending in a predetermined direction, the finger electrode portion being a region in which a collector electrode is disposed, in plan view of a photoelectric conversion section. The finger electrode portion has a stacked structure in which a first conductive layer and a second conductive layer having a lower resistance than the first conductive layer are stacked on the photoelectric conversion section. A wiring member is arranged on the collector electrode in a manner to intersect the finger electrode portion. An intersecting region between the finger electrode portion 31 of the solar cell and the wiring member has a lamination structure in which the first conductive layer and the wiring member are stacked.

### TECHNICAL FIELD

The present invention relates to a solar cell module and a method for producing the same. The present invention relates particularly to the connection structure between a collector electrode and a wiring member of a solar cell.

### BACKGROUND ART

As energy problems and global environmental problems increase in severity, a solar cell has been receiving attention as an alternative energy to fossil fuel.

A solar cell has a built-in photoelectric conversion section which is composed of, for example, a semiconductor junction. The solar cell is capable of generating power by extracting carriers (electrons and positive holes) generated by applying light to the photoelectric conversion section to an external circuit.

Further, the solar cell is provided with a collector electrode for intensively and efficiently extracting the carriers generated in the photoelectric conversion section to the external circuit. The collector electrode is attached onto the photoelectric conversion section of the solar cell.

When the solar cell is used as a power source (energy source), output per a single unit solar cell is at most approximately several watts. Thus, generally, a solar cell module in which a plurality of solar cells are electrically connected in series is used. In the solar cell module, the unit solar cells are electrically connected in series to thereby add voltage applied to the photoelectric conversion section inside each of the solar cells. Accordingly, it is possible to increase output.

In this specification, “solar cell module” is defined to include not only one as described above in which a plurality of unit solar cells are connected, but also a single solar cell (hereinafter, also referred to as “unit solar cell” or “cell”).

Further, the solar cell module includes a front protective member which protects the front side (light incident surface side) of each solar cell and a back protective member which protects the back side of each solar cell. In the solar cell module, a encapsulant is filled between the front protective member and the back protective member to seal each solar cell.

Generally, a light transmissive member such as a glass substrate is used as the front protective member. A light transmissive material such as EVA (ethylene vinyl acetate) is used as the encapsulant.

The connection structure between each unit solar cell of the solar cell module will be specifically described. As described above, the solar cell module includes the collector electrodes which are disposed on the front surfaces (light receiving surfaces, light incident surfaces) of the respective unit solar cells. The collector electrodes are connected to wiring members (tabs or interconnectors, for example) to thereby electrically connect adjacent solar cells to each other or connect the solar cell and a connection wiring line of the external circuit to each other.

Examples of the solar cell include a so-called crystal silicon-based solar cell which uses a single crystal silicon substrate or a polycrystalline silicon substrate. The crystal silicon-based solar cell includes a collector electrode which is made of metal and disposed on the light receiving surface thereof. Examples of the solar cell also include a so-called heterojunction solar cell which includes an amorphous silicon layer and a transparent electrode layer on a crystal silicon substrate. Also the heterojunction solar cell includes a collector electrode disposed on the transparent electrode layer.

Examples of the solar cell also include thin film solar cells such as a silicon-based thin film solar cell which uses an amorphous silicon thin film or a crystal silicon thin film, a compound solar cell such as a CIGS solar cell and a CIS solar cell, an organic thin film solar cell, and a dye sensitized solar cell. In view of reducing the surface resistance in a light receiving surface of a photoelectric conversion section, a transparent electrode layer is formed on the light receiving surface in these solar cells.

In this manner, a collector electrode can be disposed on a light receiving surface in any kind of solar cell.

In the above structure in which the transparent electrode layer has electrical conductivity, the transparent electrode layer functions as the collector electrode. Thus, theoretically, it is not necessary to provide another collector electrode on the transparent electrode layer.

However, in practical use, conductive oxides such as indium tin oxide (ITO) and zinc oxide (ZnO) are often used as the transparent electrode layer. These conductive oxides have a higher resistivity than metal. Thus, when a conductive oxide is used as the transparent electrode layer, the internal resistance in the entire solar cell module disadvantageously increases.

Thus, conventionally, a collector electrode which is made of metal and disposed on a transparent electrode layer of a solar cell has been allowed to function as an extraction electrode. In this manner, efforts to improve the current extraction efficiency have been conventionally made (Patent Document 1, for example).

The collector electrode is allowed to function as an auxiliary electrode which supports electrical conduction of the transparent electrode layer formed of conductive oxide or an extraction electrode which extracts current. That is, it is basically only required that a predetermined thickness and area required for supporting the electrical conduction or extracting current can be ensured in the collector electrode. Thus, efforts to form the collector electrode (hereinafter, also referred to as “plating electrode”) by an electrolytic plating method or an electroless plating method have also been made (Patent Documents 2 and 3, for example). Forming the collector electrode by an electrolytic plating method or an electroless plating method can achieve cost reduction in the solar cell module.

### PRIOR ART DOCUMENT

### Patent Documents

Patent Document 1: JP 2008-135654 A

Patent Document 2: JP 2010-098232 A

Patent Document 3: JP 2013-507781 A

### DISCLOSURE OF INVENTION

### Technical Problem

In the solar cell module, the collector electrodes are connected to the wiring members (tabs or interconnectors, for example) to thereby electrically connect adjacent solar cells to each other or connect the solar cell and the external circuit to each other. Generally, each collector electrode and each wiring member are bonded to each other with solder or a conductive adhesive such as an anisotropic conductive film interposed between the collector electrode and the wiring member.

Thus, the inventor of the present invention has experimentally produced a solar cell module in such a manner that a collector electrode (plating electrode) is formed by an electrolytic plating method and a wiring member is connected to the plating electrode. In the experimentally produced solar cell module, the wiring member and the plating electrode are bonded to each other with solder in the same manner as in a conventional one.

The inventor has expected that employing the structure of the experimentally produced solar cell module makes it possible to reduce the production cost and also reduce the resistance loss between a photoelectric conversion section and the wiring member because the collector electrode is formed by a plating method.

Although the experimentally produced solar cell makes it possible to reduce the production cost and also reduce the resistance loss to some extent, another problem has become apparent.

Specifically, it has turned out that, when the plating electrode and the wiring member are bonded with solder interposed therebetween, the bonding strength between the plating electrode and a base layer thereof is weakened.

Thus, disconnection may occur in the experimentally produced solar cell due to, for example, external factors such as a shock, and is therefore unstable as a solar cell module.

Further, the inventor has also experimentally produced a solar cell module in which a wiring member and a plating electrode are bonded to each other with a conductive film (CF) instead of solder.

However, also in this experimentally produced solar cell module, the bonding strength between the plating electrode and a base layer thereof is weakened similarly to the case when solder is used.

The present invention therefore aims to provide a solar cell module having a smaller resistance loss between a photoelectric conversion section and a wiring member than a conventional one and also having a sufficient bonding strength. The present invention also aims to provide a method for producing the solar cell module capable of easily producing the solar cell module having such characteristics.

### Solution to Problem

The inventor has considered the cause of a reduction in the bonding strength described above as follows.

Specifically, when the plating electrode and the wiring member are bonded to each other with, for example, solder interposed therebetween, the plating electrode and the wiring member are substantially integrated. Thus, when load is applied to the wiring member due to external factors such as a shock, the load applied to the wiring member is intensively applied to the interface between the plating electrode and the base layer thereof. That is, the load is not dispersed throughout the interface between the wiring member and the plating layer, but intensively applied to the interface between the plating electrode and the base layer thereof. Therefore, the bonding strength between the plating electrode and the base layer thereof is particularly weakened.

One aspect of the present invention derived on the basis of the above consideration is a solar cell module including a solar cell including a photoelectric conversion section and a collector electrode; and a wiring member connecting the solar cell to an external circuit or another solar cell, wherein the solar cell includes a finger electrode portion extending in a predetermined direction, the finger electrode portion being a region in which the collector electrode is disposed. In plan view of the photoelectric conversion section, the finger electrode portion has a stacked structure in which a first conductive layer and a second conductive layer are sequentially laminated on an outer side of the photoelectric conversion section with respect to the photoelectric conversion section, the second conductive layer is a layer different from the first conductive layer, the electrical resistance of the second conductive layer is equal to or lower than the electrical resistance of the first conductive layer, the wiring member is located on an outer side of the first conductive layer with respect to the photoelectric conversion section and arranged to intersect the finger electrode portion or an extension of the finger electrode portion, and an intersecting region between the finger electrode portion of the solar cell or the extension of the finger electrode portion thereof. The wiring member has a lamination structure of the following (1) or (2):

(1) a lamination structure in which the wiring member is in direct contact with the first conductive layer

(2) a lamination structure in which the first conductive layer and the wiring member are in contact with each other through an adhesive layer that differs from the second conductive layer interposed therebetween.

In this context, “extension” represents a virtual extension. That is, “the intersecting region between the extension of the finger electrode portion and the wiring member” represents a region intersecting the wiring member if the finger electrode portion extends, that is, represents a state in which the finger electrode portion and the wiring member actually do not intersect. A example, in plan view, when the finger electrode portion intermittently extends, and the wiring member is arranged between finger electrode portions that are adjacent to each other in the extending direction, the overlapping point is the intersecting point between the extension of the finger electrode portion and the wiring member.

Further, in this context, “lamination” indicates that layers directly or indirectly overlap each other.

Further, in this context, “different layer” indicates a layer that is not completely the same as a comparison target. Examples of “the layer different from the first conductive layer” include a layer of different material and a layer that is not formed in the same step as the first conductive layer. That is, in this definition, not only a layer that is made of a different material, but also a layer that has a different composition or a different blending quantity also falls within “different layer”.

In this context, “extending” represents a state of extending “as a whole”. Even if the extending direction partially differs, a state of extending in a predetermined direction as a whole is included in “extending”. For example, even extending in zigzag state is allowed as long as extending in a predetermined direction as a whole.

In this context, “the state of extending as a whole” indicates a state in which, for example, in a material A illustrated in FIG. 27, when the width W (the length in a direction perpendicular to the extending direction of the entire material) is defined as 1, the length L (the length in the extending direction of the entire material) is 100 or more.

In this aspect, the finger electrode portion has the stacked structure in which the first conductive layer and the second conductive layer are stacked on the photoelectric conversion section. Further, the electrical resistance of the second conductive layer is equal to or less than the electrical resistance of the first conductive layer. That is, in the portion having the stacked structure, the second conductive layer functions as an auxiliary electrode which supports electrical conduction inside the first conductive layer. Thus, in this aspect, the resistance loss is smaller than the resistance loss when only the first conductive layer is provided. Also when the electrical resistance of the first conductive layer is equal to the electrical resistance of the second conductive layer, the first conductive layer and the second conductive layer form the same conductive path. Thus, the cross-sectional area of the conductive path becomes larger than that when only the first conductive layer is provided, which results in an increase in the passage amount of current. Accordingly, it is possible to suppress the resistance loss.

Further, in this aspect, the wiring member is arranged on the collector electrode in a manner to intersect the finger electrode portion or the extension of the finger electrode portion. That is, the wiring member extends in the direction intersecting the finger electrode portion. Thus, it is possible to uniformly extract current in a predetermined direction (the extending direction of the wiring member) by the wiring member. Further, it is possible to uniformly extract power in a direction perpendicular to the predetermined direction by the finger electrode portion. Therefore, it is possible to uniformly extract power within the plane of the solar cell module. Accordingly, overload is not likely to be locally applied, and partial short circuit can be prevented.

In a preferred aspect, the second conductive layer is a plating layer.

In a preferred aspect, the solar cell module further includes a light transmissive member having a light transmissive property on an outer side of the wiring member with respect to the photoelectric conversion section, wherein the solar cell is capable of collecting incident light into the photoelectric conversion section through the light transmissive member, the second conductive layer is stacked on a part of the outer surface or the entire outer surface of the wiring member with respect to the photoelectric conversion section in the intersecting region of the wiring member, and the surface roughness of the second conductive layer is larger than the surface roughness of the wiring member.

In this aspect, the second electrode having a higher surface roughness than the wiring member is stacked on a part of the wiring member or the entire wiring member in the intersecting region between the finger electrode portion of the solar cell or the extension of the finger electrode portion and the wiring member. That is, incident light from the light transmissive member is reflected by the surface of the second conductive layer having a high surface roughness in a direction that differs from the incident direction. Further, the reflected light is further reflected by the interface between the light transmissive member and air and then enters the photoelectric conversion section.

In this manner, the incident light from the light transmissive member is sealed in the inner side of the light transmissive member (the photoelectric conversion section side) with respect to the photoelectric conversion section. Thus, it is possible to reduce the optical loss compared to the case when the second conductive layer is not formed on the wiring member.

In a more preferred aspect, the solar cell module further includes an insulation layer formed on an outer side of the photoelectric conversion section with respect to the photoelectric conversion section, wherein the insulation layer has a light transmissive property.

In this aspect, the insulation layer located on the outer side of the photoelectric conversion section has a light transmissive property. Thus, it is possible to introduce light into the photoelectric conversion section without removing the insulation layer.

Further, for example, when the second conductive layer is formed by immersing the substrate in a plating bath, the second conductive layer is generally not formed in a region in which the insulation layer is formed. Thus, light is not blocked by the second conductive layer, but can be introduced into the photoelectric conversion section in the region in which the insulation layer is formed.

In a preferred aspect, the finger electrode portion includes an insulation layer interposed between the first conductive layer and the second conductive layer, the insulation layer has an opening, and the first conductive layer and the second conductive layer are electrically continuous with each other through the opening.

This aspect enables the second conductive layer to be deposited correspondingly to the shape of the opening by, for example, a plating method to thereby form the second conductive layer having a desired shape.

In a preferred aspect, the solar cell module further includes an insulation layer formed on an outer side of the photoelectric conversion section with respect to the photoelectric conversion section, wherein the side surface of the intersecting region is coated with the insulation layer across the first conductive layer and the wiring member.

In this aspect, the insulation layer is coated across the first conductive layer and the wiring member. Thus, it is possible to prevent, for example, water from entering a gap between the first conductive layer and the wiring member. Further, it is also possible to reinforce the integrated strength between the first conductive layer and the wiring member by the stiffness of the insulation layer itself.

In a preferred aspect, the solar cell module includes a plurality of the solar cells, at least two of the plurality of the solar cells are connected to each other through the wiring member. Each of the two solar cells includes a front electrode layer on the collector electrode side and a rear electrode layer on the side opposite to the collecter electrode, the front electrode layer having positive voltage or negative voltage, the rear electrode layer having voltage opposite to the front electrode layer, and the wiring member electrically connecting the front electrode layer of one of the two solar cells and the rear electrode layer of the other of the two solar cells.

In this aspect, each of the two of the plurality of the solar cells includes the front electrode layer serving as a positive electrode or a negative electrode on the collector electrode side and the rear electrode layer serving as a pole opposite to the front electrode layer on the side opposite to the collector electrode. That is, in each of the two solar cells, when the front electrode layer serves as a positive electrode, the rear electrode layer serves as a negative electrode. On the other hand, when the front electrode layer serves as a negative electrode, the rear electrode layer serves as a positive electrode.

Further, in this aspect, the wiring member electrically connects the front electrode layer of one solar cell and the rear electrode layer of the other solar cell. Thus, it is possible to electrically connect the solar cells in series.

In the above aspect, the one solar cell may be in an upside-down posture on the basis of the posture of the other solar cell.

Generally, the solar cell module is placed with the principal surface facing the sun. Thus, in this context, “upside-down posture” represents a front-rear reversed posture, that is, a state in which the front and rear of the solar cell are reversed.

In this aspect, the one solar cell is in an upside-down posture on the basis of the posture of the other solar cell. Thus, it is possible to connect the front electrode layer of the one solar cell and the rear electrode layer of the other solar cell by linearly extending the wiring member. Therefore, it is possible to easily electrically and directly connect the solar cells.

In the above aspect, the second conductive layer may not necessarily be interposed between the first conductive layer and the wiring member.

In this aspect, the second conductive layer is not interposed between the first conductive layer and the wiring member. Thus, even when the second conductive layer is a plating layer and load is applied to the wiring member, for example, by external factors such as a shock, it is possible to prevent detachment of the wiring member due to the second conductive layer being peeled off the first conductive layer as compared to the conventional art.

In the above aspect, the wiring member may include a wiring body and a coating layer. The coating layer may be softer than the first conductive layer, and cover the surface of the wiring body. A part of the first conductive layer may bite into the coating layer.

In this context, “soft” indicates that the hardness is low.

In this aspect, a part of the first conductive layer bites into the coating layer which covers the surface of the wiring body and is softer than the first conductive layer. Thus, the wiring member is not likely to be displaced with respect to the first conductive layer. Further, when the first conductive layer and the wiring member are in direct contact, it is possible to reduce the interface resistance between the first conductive layer and the wiring member.

In the above aspect, the adhesive layer may be a conductive adhesive material.

In this context, “conductive adhesive material” represents a material that has electrical conductivity and is capable of bonding two members. The conductive adhesive material may be, for example, a solidified liquid body or a sheet-like adhesive body.

This aspect makes it possible to increase the bonding strength while maintaining the electrical conductivity.

In the above aspect, the first conductive layer may include a low melting point material having a heat flow starting temperature of 80° C. or more and 250° C. or less.

In the above aspect, the second conductive layer may include copper.

This aspect makes it possible to form the second conductive layer at a relatively lower cost than when gold or silver is used.

In the above aspect, the solar cell may include a bus bar electrode portion extending in a direction intersecting the finger electrode portion, the bus bar electrode portion being a region in which the collector electrode is disposed, in plan view of the photoelectric conversion section. The finger electrode portion may project from the bus bar electrode portion. The wiring member may be arranged to overlap the bus bar electrode portion.

In this aspect, the bus bar electrode portion is located on the extension of the finger electrode portion. Thus, the extension of the finger electrode portion intersects the wiring member.

One aspect of the present invention is a method for producing the solar cell module described above, the method including, with an outer direction defined with respect to the photoelectric conversion section, a first conductive layer forming step of forming the first conductive layer on the outer side of the photoelectric conversion section, a wiring member bonding step of connecting the wiring member to the outer side of the first conductive layer, and a plating step of forming the second conductive layer on the outer side of the first conductive layer by a plating method, in this order.

In this aspect, the second conductive layer of the collector electrode is formed by a plating method. Thus, it is possible to reduce the resistance of the collector electrode to thereby improve the conversion efficiency of the solar cell.

Further, in this aspect, the second conductive layer is formed by a plating method such as an electrolytic plating method and an electroless plating method. Thus, during the formation of the second conductive layer, the temperature does not reach a high temperature that causes damage on the photoelectric conversion section. Therefore, the photoelectric conversion section is not likely to be deteriorated. Further, since the second conductive layer is formed by a plating method in this aspect, it is possible to reduce the cost compared to the case when the second conductive layer is formed using a vacuum deposition method or a sputtering method.

One aspect of the present invention is a method for producing the solar cell module described above, the method including, with an outer direction defined with respect to the photoelectric conversion section, a first conductive layer forming step of forming the first conductive layer on the outer side of the photoelectric conversion section, a wiring member bonding step of connecting the wiring member to the outer side of the first conductive layer, an insulation layer forming step of forming the insulation layer on the outer side of the first conductive layer, and a plating step of forming the second conductive layer electrically continuous with the first conductive layer through the opening formed on the insulation layer by a plating method.

In this aspect, the second conductive layer is formed in a manner to have electrical continuity with the first conductive layer through the opening formed on the insulation layer in the plating step. Thus, it is possible to control a region in which the second conductive layer is formed by, for example, the shape of the opening.

In a preferred aspect, the first conductive layer forming step, the wiring member bonding step, the insulation layer forming step, and the plating step are performed in this order.

In a preferred aspect, the solar cell is immersed in a plating solution, and electric power is supplied to the wiring member to form the second conductive layer in the plating step.

In this aspect, the second conductive layer is formed by supplying power to the wiring member. Thus, it is possible to form the second conductive layer without allowing an electrode for plating to come into contact with the solar cell. That is, it is possible to reduce the occurrence of failures such as breakage caused by the contact of the electrode for plating in the production process, to provide high yield, and to further reduce the production cost.

In a particularly preferred aspect, the power is supplied to a region in the wiring member, the region differing from a region bonded to the solar cell to form the second conductive layer.

In this aspect, the second conductive layer is formed by supplying power to a non-bonded portion which is a region other than the bonded region between the wiring member and the solar cell. That is, the feeding point is located at a position shifted from the bonded region between the wiring member and the solar cell. Thus, it is possible to easily supply power and to easily manufacture.

In a preferred aspect, the solar cell module comprising a plurality of the solar cells, wherein each of the solar cells is connected to each other by a wiring member, and electric power is supplied to the wiring member to simultaneously form second conductive layers on the plurality of the solar cells.

This aspect makes it possible to collectively form second conductive layers on a plurality of solar cells. Thus, it is possible to improve the productivity compared to the case when the second conductive layer is formed for each solar cell.

In the above aspect, adjacent solar cells may be connected in upside-down postures from each other by the wiring member, and power may be fed to the wiring member to simultaneously form the second conductive layers on the adjacent solar cells.

This aspect makes it possible to easily attach the wiring member and to further improve the productivity.

In the above aspect, the method may include, with an outer direction defined with respect to the photoelectric conversion section, a first conductive layer forming step of forming the first conductive layer on the outer side of the photoelectric conversion section, an adhesive layer forming step of forming an adhesive layer in the form of a thin film on the outer side of the first conductive layer, and a wiring member bonding step of bonding the wiring member onto the first conductive layer through the adhesive layer in this order. In the wiring member bonding step, an opening may be formed on a part of the adhesive layer by thermocompression-bonding on the adhesive layer, and the first conductive layer and the wiring member may be allowed to have direct contact with each other through the opening.

In this aspect, the first conductive layer and the wiring member are allowed to have direct contact with each other through the opening on the adhesive layer generated by thermocompression-bonding the wiring. Thus, even when the adhesive layer has an insulation property, it is possible to ensure the electrical continuity between the first conductive layer and the wiring member.

### Effect of Invention

In the solar cell module of the present invention, the resistance loss between the photoelectric conversion section and the wiring member is smaller than in a conventional one. Further, in the solar cell module of the present invention, the bonding strength between the photoelectric conversion section and the wiring member is sufficiently large. Thus, the solar cell module has a high conversion efficiency and high reliability.

The method for producing the solar cell module of the present invention makes it possible to reduce the production cost.

### BRIEF DESCRIPTION OF DRAWINGS

FIG. 1 is a perspective view schematically illustrating a solar cell module in a first embodiment.

FIG. 2 is an exploded perspective view of a part of the solar cell module of FIG. 1.

FIG. 3 is a cross-sectional view of the solar cell module taken along a line A-A of FIG. 1.

FIG. 4 is an exploded perspective view illustrating a solar cell and wiring members of FIG. 1.

FIGS. 5(a) and 5(b) are explanatory diagrams schematically illustrating a principal part of the solar cell module of FIG. 1, wherein FIG. 5(a) is a cross-sectional view of a finger electrode portion and the vicinity thereof and FIG. 5(b) is a cross-sectional view of a bus bar electrode portion and the vicinity thereof.

FIG. 6 is an explanatory diagram of the solar cell of FIG. 1, specifically, an explanatory diagram illustrating each region.

FIG. 7 is a schematic view illustrating the cross-sectional structure inside the solar cell of FIG. 1.

FIG. 8 is a partial cutaway perspective view of a principal part of the solar cell module of FIG. 1.

FIG. 9 is a diagram illustrating a state in which an insulation layer and a second conductive layer are omitted in FIG. 8.

FIGS. 10(a) to 10(c) are explanatory diagrams schematically illustrating the finger electrode portion, the bus bar electrode portion, and the vicinities thereof in a production process of the solar cell module of FIG. 1, wherein each of FIGS. 10(a) to 10(c) illustrates a step.

FIGS. 11(d) to 11(f) are explanatory diagrams schematically illustrating the finger electrode portion, the bus bar electrode portion, and the vicinities thereof in the production process of the solar cell module of FIG. 1, wherein each of FIGS. 11(d) to 11(f) illustrates a step.

FIG. 12 is a conceptual diagram of a plating apparatus used in a plating step.

FIGS. 13(a) to 13(c) are conceptual diagrams illustrating a state of the plating step, wherein FIG. 13(a) is a diagram illustrating an example of the installation positions of an electrode contact jig and the wiring members, FIG. 13(b) is a diagram illustrating the electrode contact jig, and FIG. 13(c) is a diagram illustrating another example of the installation position of the electrode contact jig.

FIGS. 14(a) and 14(b) are cross-sectional views schematically illustrating an optical path of incident light in the solar cell module of FIG. 1 by an arrow, wherein FIG. 14(a) is a cross-sectional view of the finger electrode portion and the vicinity thereof and FIG. 14(b) is a cross-sectional view of the bus bar electrode portion and the vicinity thereof.

FIG. 15 is a partial cutaway perspective view of a principal part of a solar cell module in a second embodiment of the present invention.

FIGS. 16(a) to 16(c) are explanatory diagrams schematically illustrating a finger electrode portion, a bus bar electrode portion, and the vicinities thereof in a production process of the solar cell module of FIG. 15, wherein each of FIGS. 16 (a) to 16(c) illustrates a step.

FIGS. 17(d) to 17(f) are explanatory diagrams schematically illustrating the finger electrode portion, the bus bar electrode portion, and the vicinities thereof in the production process of the solar cell module of FIG. 15, wherein each of FIGS. 17(d) to 17(f) illustrates a step.

FIG. 18 is a conceptual diagram of a plating apparatus used in a plating step in another embodiment.

FIG. 19 is a conceptual diagram of a plating apparatus used in a plating step in another embodiment.

FIG. 20 is a conceptual diagram of a plating apparatus used in a plating step in another embodiment.

FIG. 21 is a cross-sectional view schematically illustrating a solar cell in another embodiment.

FIG. 22 is a diagram illustrating the refractive index (n) and the extinction coefficient (k) in each wavelength of an insulation layer formed on a light incident surface side.

FIGS. 23(a) and 23(b) are explanatory diagrams schematically illustrating a principal part of a solar cell module of another embodiment, wherein FIG. 23(a) is a cross-sectional view of a finger electrode portion and the vicinity thereof and FIG. 23(b) is a cross-sectional view of a bus bar electrode portion and the vicinity thereof.

FIG. 24 is an explanatory diagram of the connection structure of wiring members between solar cells in another embodiment.

FIG. 25 is a cross-sectional view of a bus bar electrode portion and the vicinity thereof in another embodiment.

FIGS. 26(a) to 26(c) are explanatory diagrams of a method for forming a hole in another embodiment, wherein FIG. 26(a) illustrates a step of forming a resist layer on a first conductive layer, FIG. 26(b) illustrates a step of forming a second conductive layer, and FIG. 26(c) illustrates a step of peeling off the resist layer.

FIG. 27 is an explanatory diagram illustrating a material in an extended state.

### MODE FOR CARRYING OUT THE INVENTION

Hereinafter, embodiments of the present invention will be specifically described.

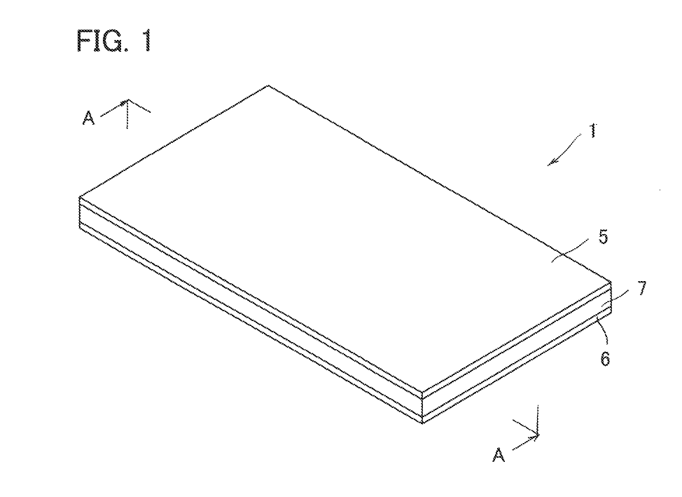

In the following description, the upper-lower positional relationship of a solar cell module 1 will be described on the basis of the posture in FIG. 1 unless otherwise noted. Each of the drawings may be drawn in an exaggerated manner as a whole compared to an actual size (length, width, and thickness) in order to facilitate understanding.

In this specification, a component having a volume resistivity of 10⁻² Ω·cm or less is defined as a conductive component. On the other hand, a component having a volume resistivity of 10² Ω·cm or more is defined as an insulation component. In the following description, in principle, when the front and rear sides of the entire solar cell 2 are described, the front surface is referred to as a first principal surface and the rear surface is referred to as a second principal surface. Further, in the following description, the inner and outer sides are described on the basis of a photoelectric conversion section 30 unless otherwise noted.

The solar cell module 1 in the first embodiment is obtained by modularizing the solar cells 2 when put to practical use.

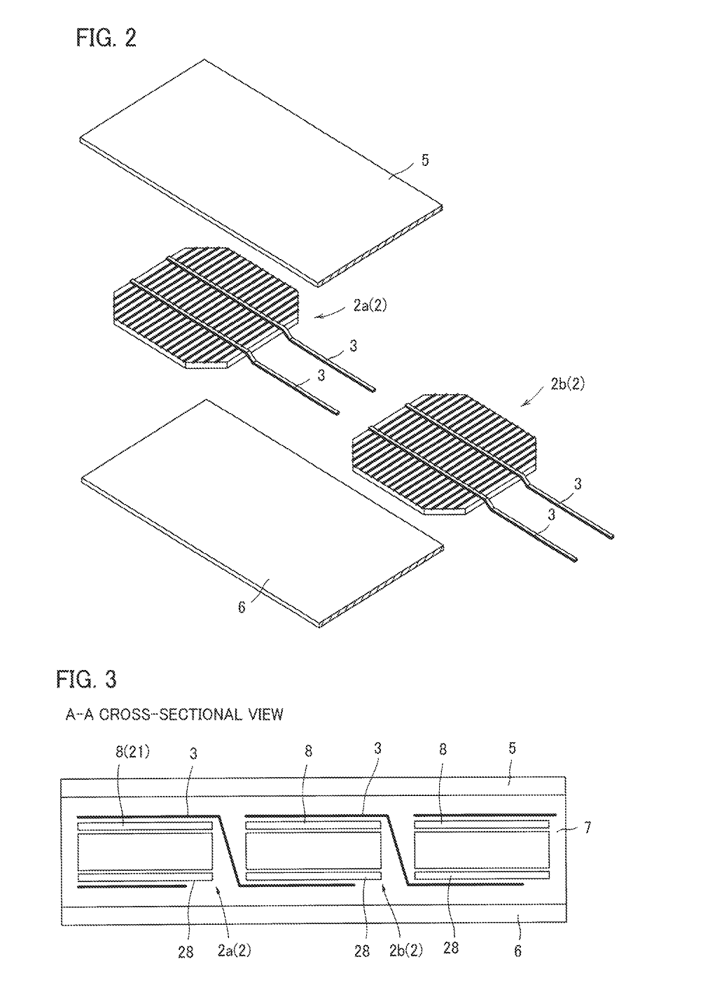

Specifically, as illustrated in FIGS. 2 and 3, the solar cell module 1 is formed of a plurality of the solar cells 2 (2a, 2b) which are electrically connected in series or in parallel by wiring members 3. In the present embodiment, the solar cell module 1 which includes the solar cells 2 which are electrically connected in series by the wiring members 3 will be described.

As illustrated in FIGS. 1 and 3, the solar cell module 1 includes a front surface member 5 (light transmissive member) and a rear surface member 6 between which the plurality of the solar cells 2 are interposed. An encapsulant 7 is filled and sealed between the front surface member 5 and the rear surface member 6 in a manner to allow the solar cells 2 to be buried therein.

As illustrated in FIG. 3, in the solar cell module 1, a collector electrode 8 (positive electrode) disposed on the first principal surface (light receiving surface) of one solar cell 2 and a rear electrode 28 (rear electrode layer, negative electrode) disposed on the second principal surface of the other solar cell 2 are connected to each other by the wiring members 3. Thus, the adjacent solar cells 2 are electrically connected to each other in series.

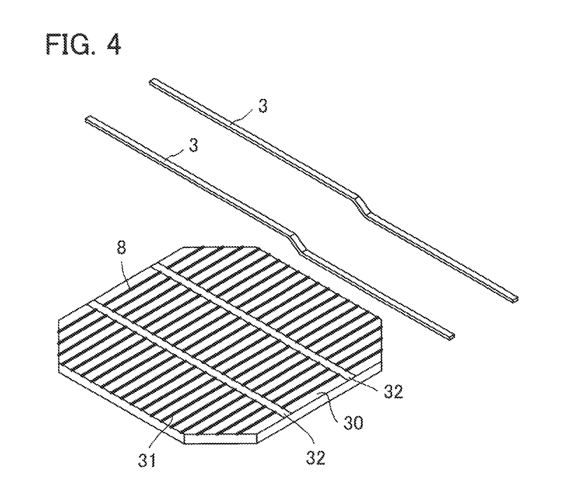

As illustrated in FIG. 4, each of the solar cells 2 includes the photoelectric conversion section 30 having a photoelectric conversion function.

That is, the solar cell 2 collects incident light passing through the front surface member 5 by the photoelectric conversion section 30 to generate power.

As illustrated in FIG. 4, the comb-shaped collector electrode 8 is disposed on the front surface (light receiving surface) of the photoelectric conversion section 30.

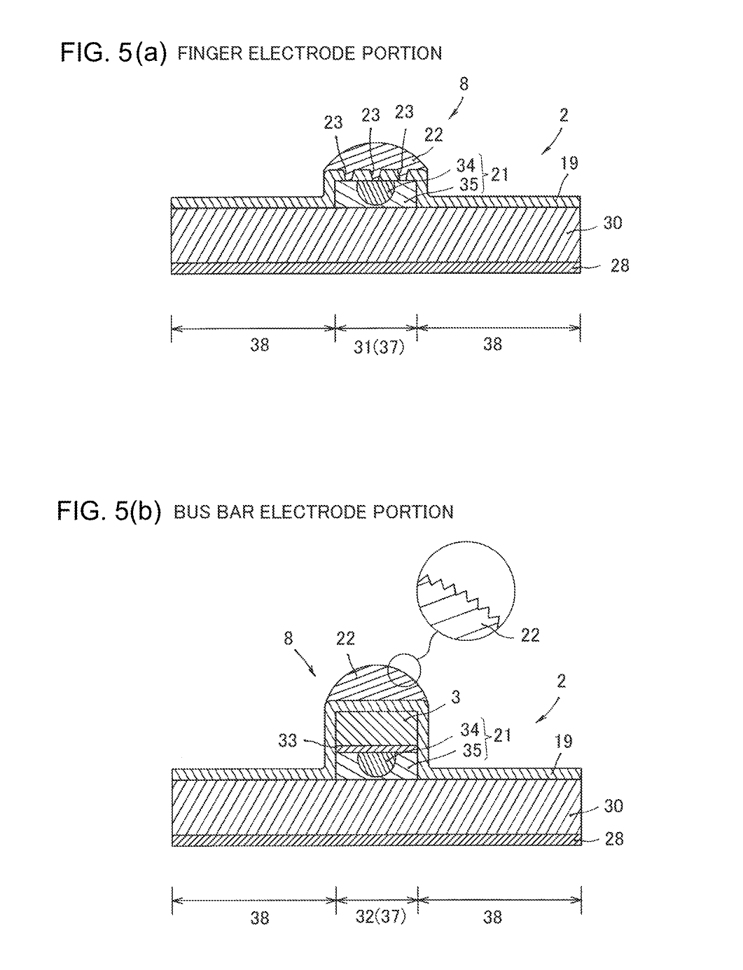

As illustrated in FIGS. 5(a) and 5(b), the collector electrode 8 includes a first conductive layer 21 and a second conductive layer 22 which are formed in this order from the side of the photoelectric conversion section 30. An insulation layer 19 is interposed between the first conductive layer 21 and the second conductive layer 22. In other words, the second conductive layer 22 is formed on the side opposite to the first conductive layer 21 across the insulation layer 19.

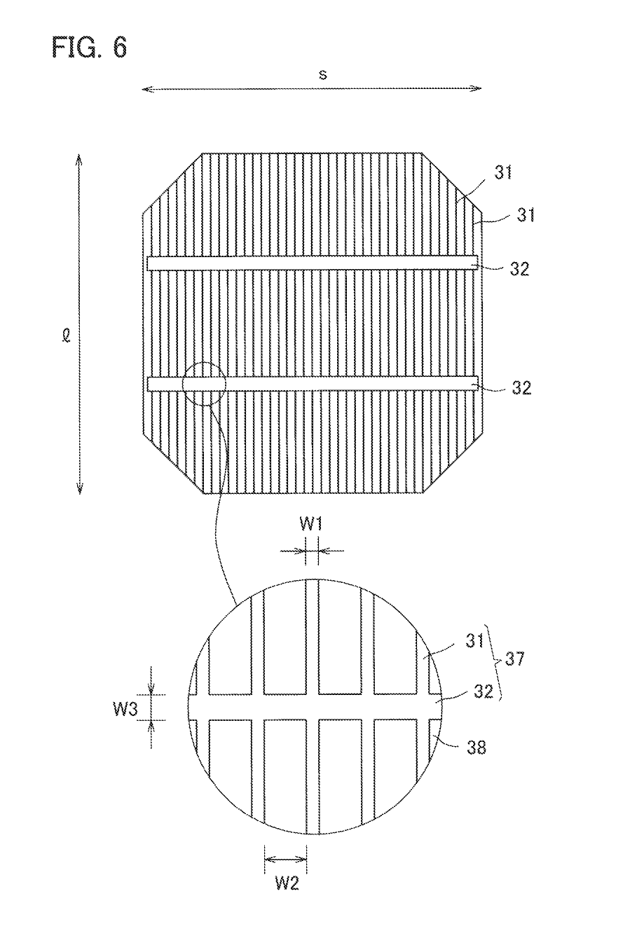

As can be seen from FIGS. 5(a), 5(b), and 6, the solar cell 2 includes a first conductive layer forming region 37 in which the photoelectric conversion section 30 is coated with the first conductive layer 21 and a first conductive layer non-forming region 38 which is a region other than the first conductive layer forming region 37 in plan view of the photoelectric conversion section 30. The first conductive layer forming region 37 includes a plurality of (a larger number of) finger electrode portions 31 and a plurality of bus bar electrode portions 32.

As illustrated in FIG. 6, each of the finger electrode portions 31 is a linear region in which the first conductive layer 21 extends in a length direction 1.

The finger electrode portions 31 are arranged to be distributed on the front surface (light receiving surface) of the photoelectric conversion section 30. That is, the finger electrode portions 31 are arranged at predetermined intervals in a width direction s. Further, the finger electrode portions 31 are arranged side by side at equal intervals to be parallel to each other.

The width (the length in the width direction) W1 of each of the finger electrode portions 31 illustrated in an enlarged view of FIG. 6 is preferably 10 μm or more, and more preferably 30 μm or more in view of disconnection prevention.

The width W1 of each of the finger electrode portions 31 is preferably 150 μm or less, and more preferably 90 μm or less in view of introducing a larger amount of light to the photoelectric conversion section 30.

An interval (pitch) W2 between the finger electrode portions 31 is preferably 0.5 mm or more, and more preferably 1 mm or more in view of introducing a larger amount of light to the photoelectric conversion section 30.

The interval W2 between the finger electrode portions 31 is preferably 4 mm or less, and more preferably 2.5 mm or less in view of making the distribution of current within a plane of the photoelectric conversion section 30 more uniform.

As illustrated in FIG. 6, each of the bus bar electrode portions 32 is a band-shaped region in which the first conductive layer 21 extends in the width direction s (the direction perpendicular to the length direction).

The bus bar electrode portions 32 are arranged to be distributed on the front surface (light receiving surface) of the photoelectric conversion section 30. The bus bar electrode portions 32 are arranged at predetermined intervals in the length direction 1. Further, the bus bar electrode portions 32 are arranged side by side to be parallel to each other.
The number of bus bar electrode portions 32 is smaller than the number of finger electrode portions 31. Specifically, the number of bus bar electrode portions 32 is preferably one or more and five or less, and more preferably two or more and four or less.

The width (the length in the length direction) W3 of each of the bus bar electrode portions 32 is preferably 0.3 mm or more in view of ensuring a sufficient conductive path, and more preferably 0.9 mm or more in view of reliably preventing disconnection or the like.

The width W3 of each of the bus bar electrode portions 32 is preferably 3 mm or less, and more preferably 2.1 mm or less in view of allowing a larger amount of light to enter the photoelectric conversion section 30.

The positional relationship between the finger electrode portions 31 and the bus bar electrode portions 32 will be briefly described. The finger electrode portions 31 and the bus bar electrode portions 32 extend in a comb-like shape. That is, the bus bar electrode portions 32 extend in the width direction s as illustrated in FIG. 6. The finger electrode portions 31 project from an intermediate region of each of the bus bar electrode portions 32 in a direction perpendicular thereto in the plane direction.

In the present embodiment, two bus bar electrode portions 32 extend in parallel to each other, and a large number of finger electrode portions 31 extend across the two bus bar electrode portions 32. That is, a plurality of finger electrode portions 31 extend in a manner to project from a single bus bar electrode portion 32 in the direction perpendicular thereto.

The insulation layer 19 has an insulation property. The insulation layer 19 has holes 23 (openings) which penetrate the insulation layer 19 in the member thickness direction as illustrated in FIG. 5(a).

The first conductive layer 21 and the second conductive layer 22 are physically connected to each other through the openings of the holes 23 of the insulation layer 19. That is, the second conductive layer 22 is partially electrically continuous with the first conductive layer 21 through the openings of the holes 23 of the insulation layer 19.

In this context, “partially electrically continuous” indicates a partially electrically connected state, and includes electrostatic continuity. Typically, openings are formed on the insulation layer 19, and the material of the second conductive layer 22 is filled in the openings, thereby achieving electrical continuity.

As illustrated in FIG. 5(a), the insulation layer 19 is located at least on the finger electrode portions 31. The insulation layer 19 is preferably formed across the first conductive layer non-forming regions 38, and particularly preferably formed on substantially the entire surface.

In this context, “substantially the entire surface” indicates 90% or more of a reference surface. That is, the insulation layer 19 is laminated on 90% or more of one side of a lamination object (the photoelectric conversion section 30 or the like in the present embodiment). The insulation layer 19 is particularly preferably laminated on the entire surface of a lamination object (the photoelectric conversion section 30 or the like in the present embodiment).

Hereinafter, “substantially the entire surface” is defined as 90% or more of the reference surface.

As described above, the insulation layer 19 is also formed on the first conductive layer non-forming regions 38. Thus, when the second conductive layer 22 is formed by a plating method, the insulation layer 19 is capable of chemically and electrically protecting the photoelectric conversion section 30 from a plating solution.

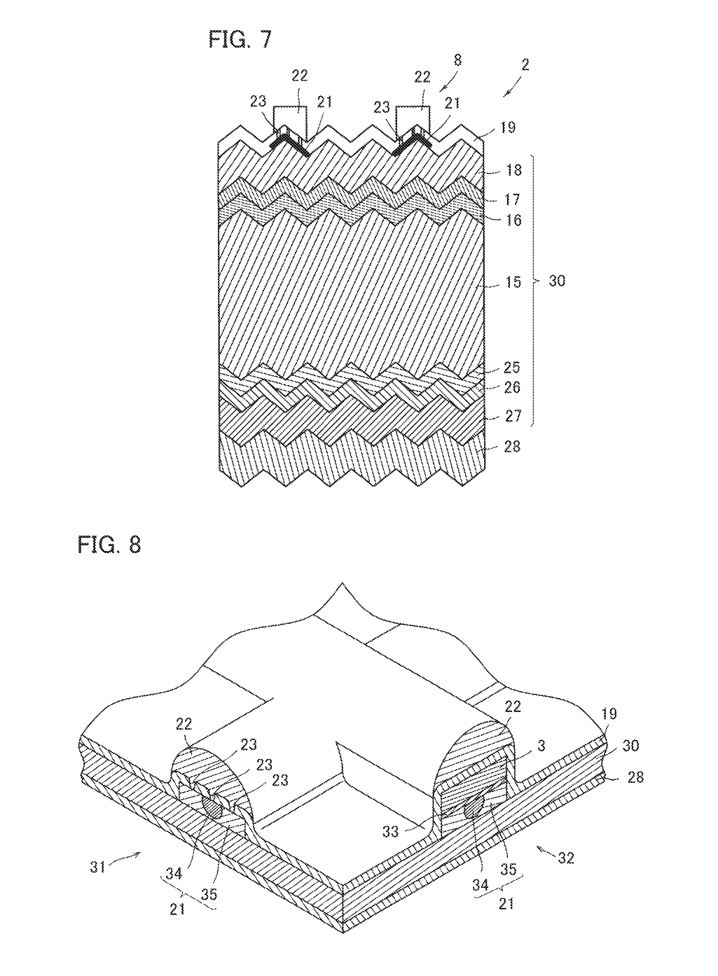

Specifically, when a transparent electrode layer 18 (described below, refer to FIG. 7) is formed on the front surface (light incident surface) of the photoelectric conversion section 30 as in the solar cell 2 of the present embodiment, the transparent electrode layer 18 is exposed to the plating solution and may thereby be eroded.

Thus, in the solar cell 2 of the present embodiment, forming the insulation layer 19 on the front surface of the transparent electrode layer 18 (front electrode layer) prevents the transparent electrode layer 18 from having direct contact with the plating solution. Therefore, it is possible to prevent deposition of the metal layer (the second conductive layer 22) on the transparent electrode layer 18 by the insulation layer 19. Further, it is also possible to prevent the erosion of the transparent electrode layer 18 caused by the plating solution by the insulation layer 19.

Also in view of the productivity, the insulation layer 19 is more preferably formed on the entire area of the first principal surface of the photoelectric conversion section 30. In the present embodiment, the insulation layer 19 is formed to cover substantially the entire area of the first principal surface of the photoelectric conversion section 30.

As illustrated in FIG. 4, each of the wiring members 3 is a long member, specifically, a foil-like or plate-like member having electrical conductivity. As the wiring member 3, for example, a thin plate which is made of metal, for example, copper onto which metal plating is applied may be employed. That is, the wiring member 3 includes not only a metal simple substance, but also metal onto which surface treatment such as plating is applied.

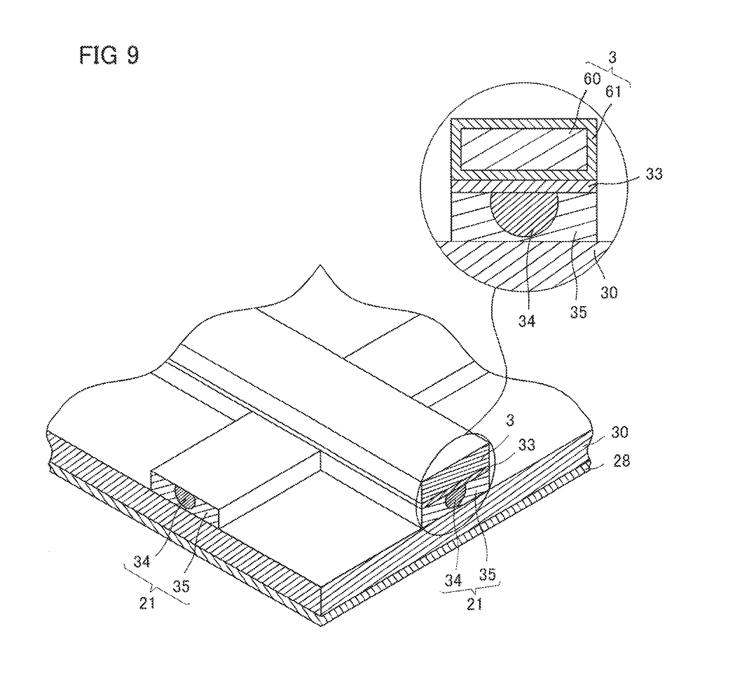

As illustrated in an enlarged view of FIG. 9, the wiring member 3 of the present embodiment includes a wiring body 60 and a coating layer 61 which covers the surface of the wiring body 60.

The wiring body 60 is a base of the wiring member 3 and formed of a conductor.

The contacting layer 61 protects the wiring body 60 from an external damage and the like. The coating layer 61 is formed of a softer layer than the first conductive layer 21.

Specifically, as the wiring member 3 of the present embodiment, copper foil having a solder-plated surface is employed. That is, the wiring body 60 is formed of copper foil, and the coating layer 61 is formed of, for example, solder.

As illustrated in FIG. 5(b), the wiring member 3 is physically and electrically connected to the first conductive layer 21 of the solar cell 2 with an adhesive material 33 interposed therebetween.

The width and the thickness of the wiring member 3 is determined by taking the number of wiring members 3 connected to the solar cell 2 into consideration. The width of the wiring member 3 is preferably 0.5 mm or more and 2.5 mm or less. The thickness of the wiring member 3 is preferably 50 μm or more and 500 μm or less.

The length of the wiring member 3 is not particularly limited to any length. However, the length of the wiring member 3 is desirably longer than the length of one side of the solar cell 2. The length of the wiring member 3 is more preferably longer than the length in the lateral direction (width direction) of the photoelectric conversion section 30 as illustrated in FIG. 2 so that the wiring member 3 extends to the outside of the solar cell 2.

In the present embodiment, as illustrated in FIG. 3, the length of the wiring member 3 extends beyond the width of the solar cell 2a and further extends up to the adjacent solar cell 2b.

As illustrated in FIG. 2, the front surface member 5 (light transmissive member) is a light transmissive plate-like or sheet-like member which covers the first principal surface (light incident surface) of the solar cell 2. As the material of the front surface member 5, glass, light transmissive plastic, or the like may be employed.

As illustrated in FIG. 2, the rear surface member 6 is a plate-like or film-like member which covers the second principal surface of the solar cell 2. As the rear surface member 6, a resin film such as a polyethylene terephthalate film, a steel plate, a glass plate, or the like may be employed.

As illustrated in FIGS. 1 and 3, the encapsulant 7 is filled between the front surface member 5 and the rear surface member 6 to seal the solar cells 2. The encapsulant 7 is an adhesive material having a light transmissive property and insulation property. Specifically, the encapsulant 7 is a resin adhesive containing a resin.

As the resin adhesive having an insulation property, for example, EVA (ethylene vinyl acetate) which is an ethylene-vinyl acetate copolymer resin or a thermosetting resin such as polyvinyl butyral may be employed.

Next, the positional relationship between each of the members of the solar cell module 1 will be described. The detailed configuration of each of the members of the solar cell module 1 will described further below.

First, the finger electrode portion 31 in the first conductive layer forming region 37 will be specifically described. As illustrated in FIG. 5(a), in the solar cell 2, the first conductive layer 21 is stacked on the front surface of the photoelectric conversion section 30 to have direct contact therewith.

The first conductive layer 21 is coated with the insulation layer 19, and the second conductive layer 22 is stacked thereon. As described above, the second conductive layer 22 is directly physically connected to the first conductive layer 21 through the holes 23 of the insulation layer 19.

The second conductive layer 22 is buried in the holes 23 of the insulation layer 19. Adjacent holes 23, 23 are connected to each other through the second conductive layer 22. Thus, the electrical conductivity between the first conductive layer 21 and the wiring member 3 is supported by the second conductive layer 22 which has a lower electrical resistance than the first conductive layer 21. Therefore, it is possible to reduce the resistance loss between the first conductive layer 21 and the wiring member 3.

The bus bar electrode portion 32 in the first conductive layer forming region 37 will be specifically described. As illustrated in FIG. 5(b), in the solar cell 2, the first conductive layer 21 is stacked on the front surface of the photoelectric conversion section 30 to have direct contact therewith. The wiring member 3 is bonded onto the first conductive layer 21 with the adhesive material 33 (adhesive layer) interposed therebetween.

Non-bonded surfaces of the first conductive layer 21 and the wiring member 3 are coated with the insulation layer 19, and the second conductive layer 22 is partially or entirely stacked thereon. That is, the side surfaces of the first conductive layer 21 and the wiring member 3 are coated with the insulation layer 19. Thus, the first conductive layer 21 is bonded to the wiring member 3 also with the insulation layer 19.

In other words, the bus bar electrode portion 32 is coated with the insulation layer 19 across the first conductive layer 21 and the wiring member 3.

The wiring member 3 is connected to the entire bus bar electrode portion 32. The first conductive layer 21 and the wiring member 3 are bonded to each other in a planar manner with the adhesive material 33 interposed therebetween. Thus, it is possible to ensure a sufficient conductive area.

The first conductive layer non-forming region 38 will be specifically described. As can be seen from FIG. 8, in the solar cell 2, the front surface of the photoelectric conversion section 30 is coated with the insulation layer 19. That is, the insulation layer 19 is located on the entire first conductive layer non-forming region 38.

A region in which the finger electrode portion 31 intersects the bus bar electrode portion 32 (that is, a region in which the wiring member 3 intersects the finger electrode portion 31 or an extension thereof) will be specifically described. As illustrated in FIG. 9, in the solar cell 2, the first conductive layer 21 is stacked on the front surface of the photoelectric conversion section 30 to have direct contact therewith. The wiring member 3 is bonded onto the first conductive layer 21 with the adhesive material 33 interposed therebetween. The non-bonded surfaces of the first conductive layer 21 and the wiring member 3 are coated with the insulation layer 19.

In the present embodiment, the first conductive layer 21 and the wiring member 3 are coated with the insulation layer 19.

In the entire solar cell module 1, as illustrated in FIG. 3, one end of the wiring member 3 is connected to the first conductive layer 21 which is formed on the first principal surface (front surface) of a solar cell 2a. The other end of the wiring member 3 is connected to the rear electrode 28 which is located on the second principal surface (rear surface) of the photoelectric conversion section 30 of another solar cell 2b with a known conductive adhesive material. That is, the wiring member 3 extends from the first principal surface of the solar cell 2a to the second principal surface of the other solar cell 2b through a gap between the solar cell 2a and the solar cell 2b.

Next, the detailed configuration of each of the members of the solar cell module 1 will be described. Description of points overlapping with the above description will be omitted.

As illustrated in FIGS. 5(a) and 5(b), the first conductive layer 21 has both a low melting point material 34 and a high melting point material 35. Both the low melting point material 34 and the high melting point material 35 preferably have electrical conductivity.

The low melting point material 34 (base material) generates a thermal flow in an annealing step to thereby generate a change in the surface shape of the first conductive layer 21. As the low melting point material 34, a simple substance or an alloy of a low melting point metal material or a mixture of a plurality of low melting point metal materials may be preferably used. Examples of the low melting point metal material include, for example, indium, bismuth, and gallium.

A heat flow starting temperature T1 of the low melting point material 34 is preferably lower than an annealing temperature Ta.

In this context, “the heat flow starting temperature” indicates a temperature at which the material generates a heat flow by heating, and the surface shape of the layer including the low melting point material 34 thereby changes. Typically, the heat flow starting temperature is the melting point.

Materials such as a polymer material and glass may be softened at a temperature lower than the melting point to thereby generate a heat flow. In these materials, the heat flow starting temperature can be defined to be equal to the softening point.

The softening point is a temperature at which the viscosity becomes 4.5×10⁶ Pa·s. That is, the heat flow starting temperature in this case is the same as the definition of the softening point of glass.

As will be described below, the first conductive layer 21 of the present embodiment is annealed at the annealing temperature Ta, which is lower than a heat resistant temperature of the photoelectric conversion section 30, at the time of producing the solar cell module 1. Thus, the heat flow starting temperature T1 of the low melting point material 34 is preferably lower than the heat resistant temperature of the photoelectric conversion section 30 in view of preventing damage to the photoelectric conversion section 30.

In this context, “the heat resistant temperature of the photoelectric conversion section 30” indicates a temperature at which the characteristics of the solar cell 2 are irreversibly deteriorated.

In the solar cell 2 of the present embodiment, the characteristics of a substrate 15 which constitutes a skeletal structure of the photoelectric conversion section 30 illustrated in FIG. 7 are not likely to change even when the substrate 15 is heated to a high temperature of 500° C. or more.

However, when amorphous silicon-based thin films are used as silicon-based thin films 16, 17, and 25, or when transparent conductive oxides are used as transparent electrode layers 18 and 27, heating to approximately 250° C. may cause thermal deterioration or diffusion of doped impurities, resulting in an irreversible lowering of the characteristics of the solar cell.

Therefore, in the solar cell 2 of the present embodiment, the first conductive layer 21 preferably includes the low melting point material 34 having a heat flow starting temperature T1 of 250° C. or less.

The lower limit of the heat flow starting temperature T1 of the low melting point material 34 is not particularly limited to any value.

The low melting point material 34 preferably substantially does not generate a heat flow in a step of forming the first conductive layer 21 in view of increasing the amount of a change in the surface shape of the first conductive layer 21 in the annealing step (described below) to easily form the holes 23 of the insulation layer 19.

For example, when the first conductive layer 21 is formed by coating or printing, heating may be performed for drying. In this case, the heat flow starting temperature T1 of the low melting point material 34 is preferably higher than the heating temperature for drying the first conductive layer 21. In view of this, the heat flow starting temperature T1 of the low melting point material 34 is preferably 80° C. or more, and more preferably 100° C. or more.

The low melting point material 34 may be an organic substance or an inorganic substance as long as the heat flow starting temperature T1 is within the above range.

The low melting point material 34 may be an electrically conductive material or an electrically insulating material. However, the low melting point material 34 is desirably a metal material having electrical conductivity in view of allowing the low melting point material 34 to constitute a part of the conductive path between the photoelectric conversion section 30 and the wiring member 3.

When the low melting point material 34 is a metal material, it is possible to make a value of the resistance of the first conductive layer 21 smaller than that when another material is used. Thus, when the second conductive layer 22 is formed by electrolytic plating, it is possible to improve the uniformity in the film thickness of the second conductive layer 22. Further, when the low melting point material 34 is a metal material, it is also possible to reduce the contact resistance between the photoelectric conversion section 30 and the collector electrode 8.

When a particulate low melting point material such as metal particles is used as the low melting point material 34, a particle diameter DL of the low melting point material 34 is preferably 1/20 or more of a film thickness d of the first conductive layer 21, and more preferably 1/10 or more of the film thickness d.

This range of the particle diameter DL enables easy formation of the openings on the insulation layer 19 in the annealing step.
The particle diameter DL of the low melting point material 34 is preferably 0.25 μm or more, and more preferably 0.5 μm or more.

The high melting point material 35 which constitutes a part of the first conductive layer 21 has a heat flow starting temperature (melting point) T2 which is relatively higher than that of the low melting point material 34.

As the high melting point material 35, for example, a simple substance of a metal material such as silver, aluminum, and copper, or a plurality of metal materials or an alloy thereof may be preferably used.

The first conductive layer 21 is a layer that functions as a conductive base layer when the second conductive layer 22 is formed by a plating method. Thus, the first conductive layer 21 is only required to have an electrical conductivity that can allow the first conductive layer 21 to function as the base layer for electrolytic plating. Specifically, the volume resistivity of the first conductive layer 21 is 10⁻² Ω·cm or less, and preferably 10⁻⁴ Ω·cm or less.

An average film thickness of the first conductive layer 21 is preferably 20 μm or less, and more preferably 10 μm or less in view of cost reduction.

Further, the average film thickness is preferably 0.5 μm or more, and more preferably 1 μm or more in view of allowing the line resistance of the first conductive layer 21 to fall within a desired range.

A method for forming the first conductive layer 21 is not particularly limited to any method. The first conductive layer 21 may be formed by known techniques such as an ink jet method, a screen printing method, a wire bonding method, a spray method, a vacuum deposition method, a sputtering method, an electrolytic plating method, and an electroless plating method. The first conductive layer 21 may be formed, for example, using conductive pastes as the low melting point material 34 and the high melting point material 35 by a screen printing method. The first conductive layer 21 may also be formed, for example, using a mask corresponding to the pattern shape by a deposition method or a sputtering method.

The first conductive layer 21 of the present embodiment is patterned into a predetermined shape, for example, a comb-like shape. Thus, a screen printing method is suitable for forming the patterned first conductive layer 21 in view of the productivity. Using a screen printing method also makes it possible to reduce the thickness of the first conductive layer 21, to reduce the amount of use of the first conductive layer 21, and to reduce the cost.

The second conductive layer 22 can be formed by either plating method of an electroless plating method and an electrolytic plating method. However, in view of productivity, an electrolytic plating method is preferably used. In an electrolytic plating method, it is possible to increase the deposition rate of metal by changing current or the like. Thus, it is possible to form the second conductive layer 22 in a short time.

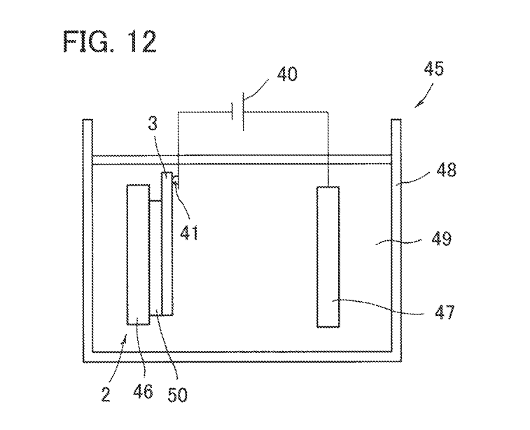

In the present embodiment, the second conductive layer 22 is formed by an electrolytic plating method using the surface of the first conductive layer 21 as the surface to be plated. In the electrolytic plating method, it is necessary to supply power from a plating power source 40 to the surface to be plated. As illustrated in FIG. 12, a feeding point 41 from the plating power source 40 is desirably arranged on the wiring member 3.

When the wiring member 3 and a solar cell substrate 46 are bonded to each other, it is more desired that a part (non-bonded portion) that is not bonded to the solar cell substrate 46 (the solar cell 2 before the second conductive layer 22 is stacked thereon) be provided in the wiring member 3, and the feeding point 41 be arranged on the part which is not bonded to the solar cell substrate 46 in the plating step (described below).

Accordingly, it is possible to more reliably prevent damage of the solar cell substrate 46 caused by contact between a contact jig and the solar cell substrate 46 at the feeding point 41. Further, it is possible to allow the wiring member 3 having a small electrical resistance to bear part of the continuity between the surface to be plated of the solar cell substrate 46 and the feeding point 41. This enables a material having a large electrical resistance to be applied to the first conductive layer 21. Thus, it is also possible to expand the range of choices in the material of the first conductive layer 21.

The solar cell substrate 46 is immersed in a plating bath, and current is applied to the wiring member 3. Accordingly, it is possible to form the second conductive layer 22 on the surface of the wiring member 3 except a part bonded to the first conductive layer 21 and the insulation layer 19. This makes it possible to further reduce the electrical resistance of the wiring member 3.

On the other hand, the front surface of the wiring member 3 (the surface opposite to the first conductive layer 21 side) is preferably coated with an insulator.

Coating the front surface of the wiring member 3 with the insulator makes it possible to reduce the consumption of metal ions within a plating solution near the front surface of the wiring member 3.

In view of the appearance (design) of the solar cell, the reflectance of the second conductive layer 22 and the reflectance of the wiring member 3 are preferably low. Further, the reflectance of the second conductive layer 22 and the reflectance of the wiring member 3 are more preferably substantially equal.

In this context, “the reflectances are substantially equal” indicates that a difference between the reflectances is within 3% of the reflectances.

In view of the appearance (design) of the solar cell, the surface of the second conductive layer 22 and the surface of the wiring member 3 are preferably coated with the same low reflective material.

Examples of the low reflective material include nickel and chromium.

In view of the productivity, the low reflective material on the second conductive layer 22 and the low reflective material on the wiring member 3 are preferably simultaneously formed.
In the present invention, this can be achieved, for example, by forming a second plating layer (the plating layer on the outer side of the second conductive layer 22) in addition to the second conductive layer 22 by using the same low reflective material as the coating layer 61 which forms the surface of the wiring member 3.

The surface roughness of the second conductive layer 22 is larger than the surface roughness of the wiring member 3. The second conductive layer 22 is formed by a plating method, and therefore has microscopic asperities.

The insulation layer 19 illustrated in FIG. 8 which covers the photoelectric conversion section 30 will be specifically described. The insulation layer 19 is a layer having an electrically insulating property.

The insulation layer 19 is formed of a material that has a chemical stability to the plating solution used in the formation of the second conductive layer 22. That is, since the material that has a chemical stability to the plating solution is used for the insulation layer 19, the insulation layer 19 is not likely to dissolve in the plating solution in the plating step when forming the second conductive layer 22.

Further, a material that has a high bonding strength to the photoelectric conversion section 30 is preferably employed as the insulation layer 19. That is, the insulation layer 19 of the solar cell 2 of the present embodiment preferably has a high bonding strength to the transparent electrode layer 18 on the light incident side located on the front surface of the photoelectric conversion section 30 as illustrated in FIG. 7.

When the bonding strength between the transparent electrode layer 18 and the insulation layer 19 is high, the insulation layer 19 is not likely to be peeled off during the plating step. As a result, it is possible to prevent the deposition of metal on the transparent electrode layer 18.

The insulation layer 19 is preferably formed of a material having a weak light absorption.

As described above, the insulation layer 19 is formed on the light incident side of the photoelectric conversion section 30. Thus, when light absorption by the insulation layer 19 is weak, it is possible to introduce a larger amount of light into the photoelectric conversion section 30.

Specifically, the transmittance of the insulation layer 19 is preferably 90% or more. When the insulation layer 19 has such a sufficient transparency, optical loss caused by light absorption in the insulation layer 19 is small. Thus, it is possible to use the solar cell 2 as it is without removing insulation layer 19 after the formation of the second conductive layer 22. Further, it is possible to simplify the production process of the solar cell 2, and to further improve the productivity.

When the solar cell 2 is used as it is without removing the insulation layer 19, a material that has, in addition to transparency, a sufficient weather resistance, sufficient stability to heat and humidity, and high barrier property against impurities such as metal ions and water vapor is more desirably used as the insulation layer 19.

Either material of an inorganic insulation material and an organic insulation material may be employed as the material of the insulation layer 19.

As the organic insulation material, for example, materials such as polyester, an ethylene-vinyl acetate copolymer, an acrylic resin, an epoxy resin, and polyurethane may be used.

As the inorganic insulation material, in view of the resistance to the plating solution and transparency, silicon oxide, silicon nitride, silicon oxide nitride, aluminum oxide, SiAlON, yttrium oxide, magnesium oxide, barium titanate, samarium oxide, barium tantalite, tantalum oxide, magnesium fluoride, titanium oxide, strontium titanate, zinc oxide, and the like are preferably used.

Among the inorganic insulation materials, silicon oxide, silicon nitride, silicon oxide nitride, aluminum oxide, SiAlON, yttrium oxide, magnesium oxide, barium titanate, samarium oxide, barium tantalite, tantalum oxide, magnesium fluoride, and the like are preferably used in view of the electric characteristics and adhesion with the transparent electrode layer. On the other hand, in view of enabling appropriately adjusting the refractive index, silicon oxide, silicon nitride, and the like are particularly preferably used.

These inorganic materials are not limited to one having a stoichiometric composition, and may be the one including, for example, oxygen deficiency.

The film thickness of the insulation layer 19 is appropriately set depending on the material and the formation method of the insulation layer 19.

In the present embodiment, the film thickness of the insulation layer 19 is preferably thin enough to allow the holes 23 (openings) to be formed on the insulation layer 19 by, for example, the stress on the interface generated by a change in the surface shape of the first conductive layer 21 in the annealing step (described below).

In view of the above, the film thickness of the insulation layer 19 of the present embodiment is preferably 1000 nm or less, and more preferably 500 nm or less.

Further, the optical characteristics and the film thickness of the insulation layer 19 in a region in which the first conductive layer 21 is not formed are appropriately set. This makes it possible to improve the light reflection property, to increase the amount of light introduced into the solar cell 2, and to further improve the conversion efficiency.

In order to obtain such effects, the refractive index of the insulation layer 19 is preferably lower than the refractive index of the front surface of the photoelectric conversion section 30. Further, in view of imparting appropriate antireflective characteristics to the insulation layer 19, the film thickness of the insulation layer 19 is preferably set within the range of 30 nm to 250 nm, and more preferably set within the range of 50 nm to 250 nm.

The film thickness of the insulation layer 19 in the first conductive layer forming region 37 (refer to FIG. 6) may differ from the film thickness of the insulation layer 19 in the first conductive layer non-forming region 38 (refer to FIG. 6).

For example, the film thickness of the insulation layer 19 may be set in view of easily forming the holes 23 (openings) in the annealing step in the first conductive layer forming region 37. On the other hand, the film thickness of the insulation layer 19 may be set to an optical film thickness having appropriate antireflection characteristics in the first conductive layer non-forming region 38.

The solar cell 2 of the present embodiment has the transparent electrode layer 18 (general refractive index: approximately 1.9 to 2.1) on the front surface (light incident side) of the photoelectric conversion section 30 as illustrated in FIG. 7. The refractive index of the insulation layer 19 is preferably a middle value between the refractive index of air (refractive index=1.0) and the refractive index of the transparent electrode layer 18 in order to improve a light reflection prevention effect on the interface to increase the amount of light introduced into the solar cell 2.

When the solar cells 2 are sealed and modularized as in the solar cell module 1 of the present embodiment, the refractive index of the insulation layer 19 is preferably a middle value between the refractive index of the encapsulant 7 and the refractive index of the transparent electrode layer 18.

In view of the above, the refractive index of the insulation layer 19 is preferably 1.4 to 1.9, more preferably 1.5 to 1.8, and further more preferably 1.55 to 1.75.

The refractive index in this specification is a refractive index with respect to light having a wavelength of 550 nm and a value measured by spectroscopic ellipsometry unless otherwise noted. The optical film thickness (refractive index×film thickness) of the insulation layer 19 is preferably set depending on the refractive index of the insulation layer 19 so as to improve the antireflection characteristics.

The insulation layer 19 may be formed using a known method. For example, when the insulation layer 19 is made of an inorganic insulation material such as silicon oxide and silicon nitride, dry methods such as a plasma CVD method and a sputtering method are preferably used. On the other hand, when the insulation layer 19 is made of an organic insulation material, wet methods such as a spin coat method and a screen printing method are preferably used. These methods make it possible to form a film that has fewer defects such as a pinhole and has a dense structure.

Among these methods, the insulation layer 19 is preferably formed by a plasma CVD method in view of forming a film having a denser structure.

This method makes it possible to form the insulation layer 19 having a high density not only when the film thickness of the insulation layer 19 is relatively thick, specifically, approximately 200 nm, but also when the film thickness of the insulation layer 19 is relatively thin, specifically, approximately 30 to 100 nm.

When the surface of the photoelectric conversion section 30 has a texture structure (uneven structure) as in the solar cell 2 of the present embodiment illustrated in FIG. 7, the insulation layer 19 is preferably formed by a plasma CVD method also in view of accurately forming the film also in projections and depressions of the texture.

Using the insulation layer 19 having a high density makes it possible to reduce damage to the transparent electrode layer 18 located on the front surface side (light incident side) during plating. In addition to this, using the insulation layer 19 having a high density also makes it possible to prevent the deposition of metal on the transparent electrode layer 18.

Further, the insulation layer 19 having a high density can function as a barrier layer against water or oxygen for the other layers inside the photoelectric conversion section 30. Thus, an effect of improvement in the long-term reliability of the solar cell 2 can also be expected.

A part of the insulation layer 19 located between the first conductive layer 21 and the second conductive layer 22, that is, a part of the insulation layer 19 located in the first conductive layer forming region 37 (refer to FIG. 6) may not necessarily have a continuous layer shape, but may have an island shape.

In this context, “island shape” indicates a state in which a part of the reference surface has a region in which a layer is not formed. In the present embodiment, the island shape indicates a state in which a part of the surface of the first conductive layer 21 has a region in which the insulation layer 19 is not formed.

The insulation layer 19 has a function also contributing to improvement in the adhesion between the first conductive layer 21 and the second conductive layer 22.

For example, in a case where the material of the first conductive layer 21 is silver and the material of the second conductive layer 22 is copper, when the second conductive layer 22 is formed on the first conductive layer 21 (base electrode layer) by a plating method, the adhesion between the first conductive layer 21 and the second conductive layer 22 becomes low.

Thus, the second conductive layer 22 is formed on the insulation layer 19 which is made of, for example, silicon oxide. As a result, it is expected that the adhesion of the second conductive layer 22 is improved and the reliability of the solar cell 2 is thereby improved.

The rear electrode 28 on the second principal surface side illustrated in FIG. 7 may be formed throughout substantially the entire rear surface of the photoelectric conversion section 30, or may be formed as a comb-like electrode like the collector electrode 8 on the light receiving surface side (first principal surface side).

The adhesive material 33 which is used to bond the first conductive layer 21 and the wiring member 3 to each other in the bus bar electrode portion 32 illustrated in FIG. 5(b) will be specifically described. The adhesive material 33 is, for example, an adhesive material having electrical conductivity. For example, conductive adhesives such as a solder material and a conductive film may be employed.

As the solder material, for example, eutectic solder, Sn—Ag—Cu-based solder, and tin-bismuth (SnBi)-based solder may be preferably used.

As the conductive film, for example, a conductive film (CF) and an interconnector such as a tab may be preferably used. Among conductive films, an anisotropic conductive adhesive film (ACF) is desirably used.

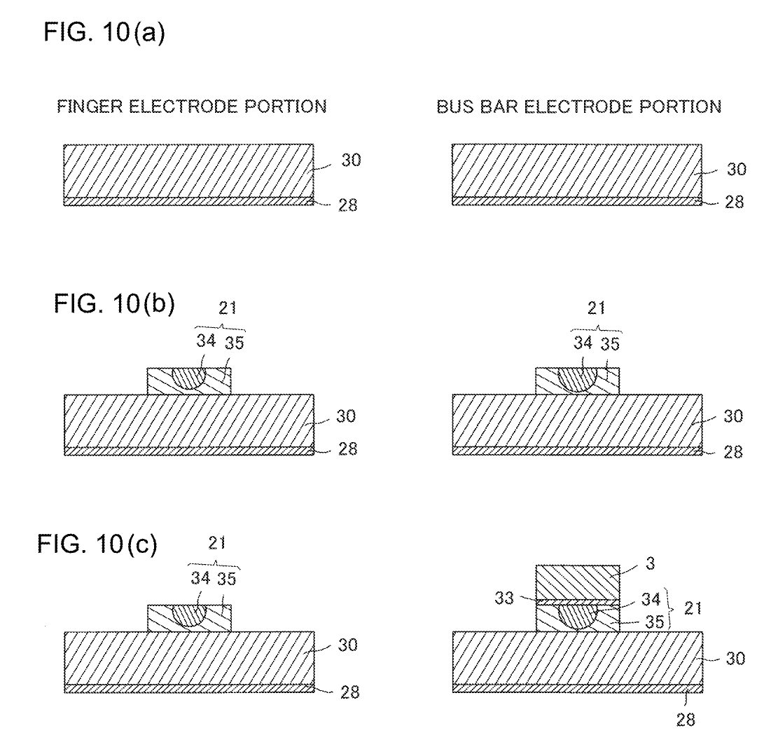

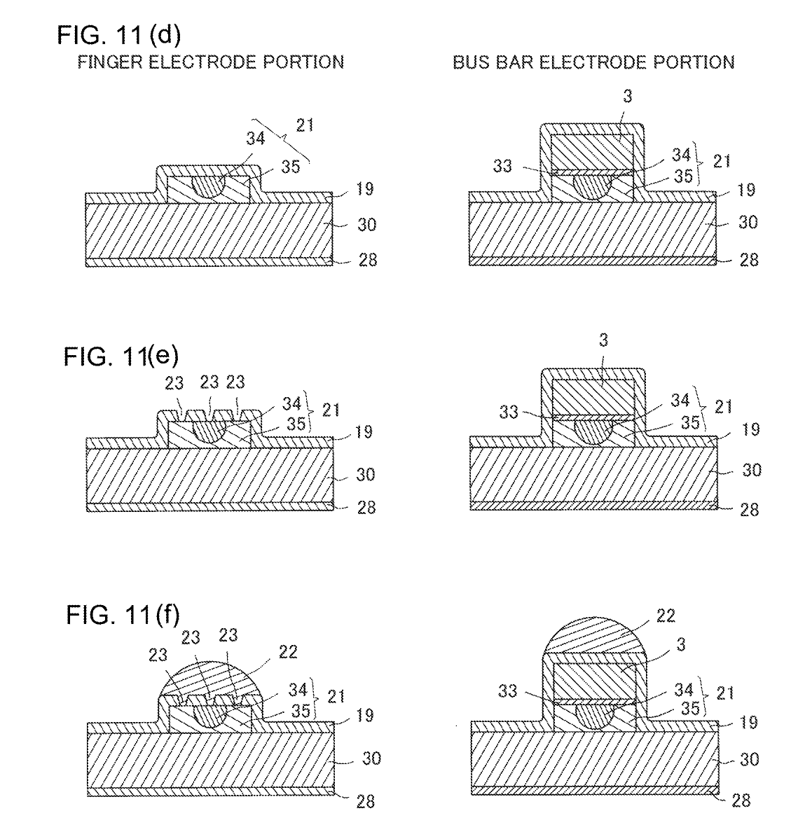

Next, a method for producing the solar cell module 1 of the present embodiment will be described. In particular, the collector electrode 8 will be specifically described. FIGS. 10(a) to 10(c) and 11(d) to 11(f) are explanatory diagrams of the production process in the finger electrode portion 31, the bus bar electrode portion 32, and the vicinities thereof.

First, as illustrated in FIG. 10(a), the photoelectric conversion section 30 is formed (a photoelectric conversion section preparing step).

Specifically, as illustrated in FIG. 7, the silicon-based thin films 16, 17, 25, and 26 and the transparent electrode layers 18 and 27, and the like are formed on the substrate 15 to from the photoelectric conversion section 30.

Then, as illustrated in FIG. 10(b), the first conductive layer 21 which includes the low melting point material 34 is formed on the front surface of the photoelectric conversion section 30 by a printing method (a first conductive layer forming step).

At this point, the first conductive layer 21 is patterned in a predetermined shape.

After the first conductive layer forming step, as illustrated in FIG. 10(c), the wiring member 3 is placed on the first conductive layer 21 inside the bus bar electrode portion 32 and bonded thereto with the adhesive material 33 (a wiring member bonding step).

At this point, the wiring member 3 and the first conductive layer 21 are bonded to each other with a planar expansion with the adhesive material 33, and have close contact with each other.

At this point, if there is a short-circuit portion between the first principal surface side and the second principal surface side in the solar cell 2, the wiring member 3 may be bonded after removing the short-circuit portion.

Then, as illustrated in FIG. 11(d), the insulation layer 19 is formed on the first conductive layer 21 and/or the wiring member 3 (an insulation layer forming step).

At this point, as can be seen from FIGS. 5(a), 5(b) and 11(d), the insulation layer 19 may be formed only on the first conductive layer 21 in the first conductive layer forming region 37, or may be formed also on the photoelectric conversion section 30 in the first conductive layer non-forming region 38 in the finger electrode portion 31 and the vicinity thereof.

Further, also in the bus bar electrode portion 32 and the vicinity thereof, the insulation layer 19 may be formed only on the wiring member 3, or may be formed also on the first conductive layer non-forming region 38.

In the present embodiment, the solar cell 2 is a heterojunction solar cell. The transparent electrode layer 18 is formed on the front surface (the surface on the light incident side) of the photoelectric conversion section 30. The insulation layer 19 is formed also on the first conductive layer non-forming region 38. That is, in the present embodiment, the insulation layer 19 is formed on the entire one principal surface (first principal surface) of the photoelectric conversion section 30.

After the formation of the insulation layer 19, as illustrated in FIG. 11(e), heating is performed at the annealing temperature Ta to perform annealing (an annealing step). At this point, the insulation layer 19 is deformed along with the deformation of the low melting point material 34, and the holes 23 are formed in the finger electrode portion 31.

The annealing temperature Ta preferably satisfies T1+1° C.≦Ta≦T1+100° C., and more preferably satisfies T1+5° C.≦Ta≦T1+60° C. The annealing temperature can be appropriately set depending on, for example, the composition and the content of the material of the first conductive layer 21.

As described above, T1 is the heat flow starting temperature of the low melting point material 34 of the first conductive layer 21.

As described above, the annealing temperature Ta is lower than the heat resistant temperature of the photoelectric conversion section 30. The heat resistant temperature of the photoelectric conversion section 30 varies depending on the configuration of the photoelectric conversion section 30.

For example, the heat resistant temperature in a heterojunction solar cell or a silicon-based thin film solar cell which has a transparent electrode layer or an amorphous silicon-based thin film like the solar cell 2 of the present embodiment is generally approximately 250° C.

Thus, in a heterojunction solar cell or a silicon-based thin film solar cell in which the photoelectric conversion section 30 includes an amorphous silicon-based thin film, the annealing temperature Ta is preferably set at 250° C. or less in view of preventing heat damage on the amorphous silicon-based thin film and the interface thereof.

In order to achieve the solar cell 2 having a higher performance, the annealing temperature Ta is more preferably 200° C. or less, and further more preferably 180° C. or less.

Along with this, the heat flow starting temperature T1 of the low melting point material 34 of the first conductive layer 21 is preferably less than 250° C., more preferably less than 200° C., and further more preferably less than 180° C.

On the other hand, a crystal silicon solar cell which has an opposite conductivity-type diffusion layer on one surface (one principal surface) of the substrate 15 does not have an amorphous silicon thin film and a transparent electrode layer. Thus, the heat resistant temperature thereof is approximately 800° C. to 900° C. Therefore, the annealing step may be performed at an annealing temperature Ta that is higher than 250° C.

After the annealing step, as illustrated in FIG. 11(f), the second conductive layer 22 is formed on the insulation layer 19 in the first conductive layer forming region 37 by a plating method (a plating step).

In the finger electrode portion 31 after the annealing, the surface of the first conductive layer 21 is coated with the insulation layer 19. The first conductive layer 21 is in an exposed state on the holes 23 formed on the insulation layer 19. Thus, in the plating step, the exposed regions of the first conductive layer 21 are exposed to the plating solution passing through the holes 23. Accordingly, the second conductive layer 22 is deposited from the holes 23 as starting points.

In the bus bar electrode portion 32 after the annealing, the surface of the wiring member 3 is coated with the insulation layer 19, and the second conductive layer 22 is deposited on a part thereof.

The method of the present embodiment makes it possible to form the second conductive layer 22 corresponding to the shape of the collector electrode 8 by a plating method without providing a resist material layer having openings corresponding to the shape of the collector electrode 8.

In this case, meal to be deposited as the second conductive layer 22 is not particularly limited to any metal as long as it can be formed by a plating method. For example, copper, nickel, tin, aluminum, chromium, silver, gold, zinc, lead, palladium, or a mixture thereof may be used.

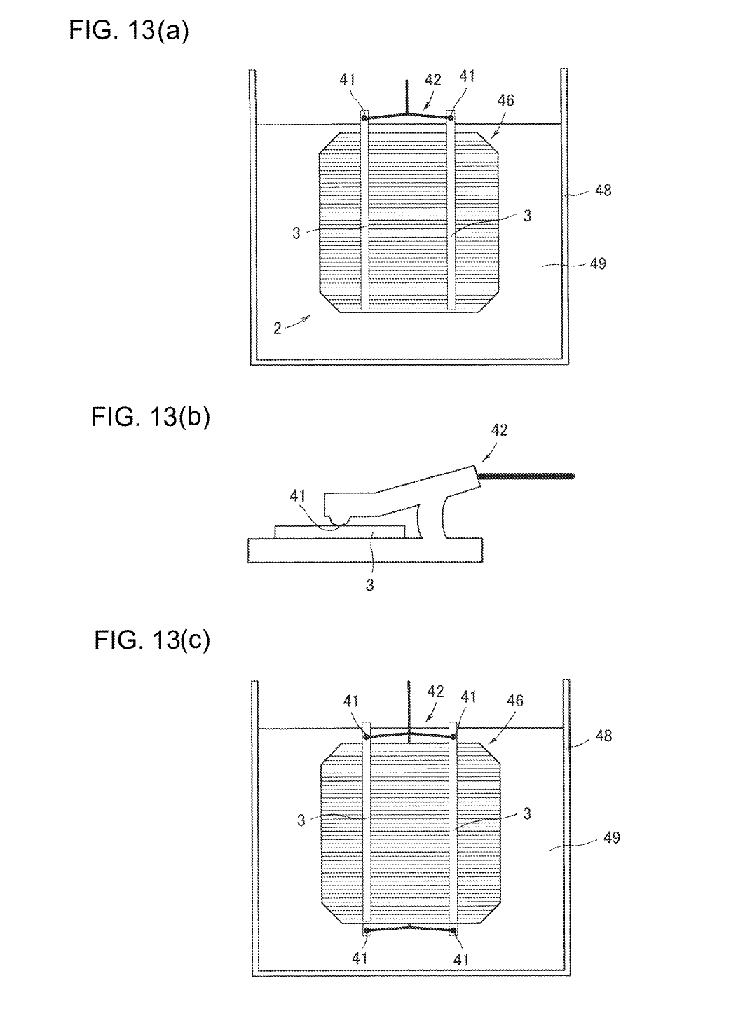

The feeding point connected from the plating power source 40 is preferably arranged on the wiring member 3 as illustrated in FIGS. 12 and 13A to 13C. Accordingly, the electrical resistance of the wiring member 3 is low, and a potential on the wiring member 3 is maintained at substantially constant even when current is applied for plating. Thus, it is possible to prevent generation of potential distribution on the surface of the solar cell 2. As a result, it is possible to prevent distribution of the deposition amount (distribution of the film thickness and line width).

In the present embodiment, as illustrated in FIG. 13(a), the feeding point 41 connected from the plating power source 40 is arranged on the wiring member 3 in a region which is not bonded to the solar cell 2 (non-bonded region). Thus, an electrode contact of the plating power source 40 does not have direct contact with the solar cell 2. The shape of an electrode contact jig 42 including the electrode contact may be designed in any shape.

An example of the electrode contact jig 42 will be described. When the electrode contact is disposed on the tip of a spring type member as illustrated in FIG. 13(b), it is possible to have contact with the wiring member 3 and, at the same time, to hold the wiring member 3 at the electrode contact. More specifically, the electrode contact jig 42 has two arms, and the wiring member 3 can be held between the two arms.

Thus, the electrode contact jig 42 makes it possible to fix the solar cell 2 at a predetermined position during the plating step.

The surface of the electrode contact jig 42 except the contact is preferably an insulator in view of preventing the deposition of metal on the surface. The feeding point 41 of the wiring member 3 and the electrode contact of the electrode contact jig 42 may have point contact at a part of the arm as illustrated in FIG. 13(b), or may have linear contact.

The number of electrode contacts may also be appropriately selected. As illustrated in FIG. 13(a), the electrode contact may be provided only in one side direction of the solar cell 2. That is, the electrode contact may be provided only on one side of the solar cell 2.

Further, as illustrated in FIG. 13(c), electrode contacts may be provided in two side directions of the solar cell 2. That is, the electrode contacts may be provided on one side of the solar cell 2 and the opposite side thereof. When the electrode contacts are provided in two side directions, the movement inside the plating bath can be restricted. Thus, it is possible to more reliably prevent damage and peel-off of the wiring member 3 during the step.

The above plating step will be described. Specifically, a method for forming the second conductive layer 22 by an electrolytic plating method will be described by taking acidic copper plating as an example.

As described above, FIG. 12 is a conceptual diagram of a plating apparatus 45 used in the formation of the second conductive layer 22.

The solar cell substrate 46 and a positive electrode 47 are immersed in a plating solution 49 in a plating bath 48.

The solar cell substrate 46 includes the first conductive layer 21 and the insulation layer 19 both formed on the photoelectric conversion section 30. Further, the annealing treatment is applied to the solar cell substrate 46 in the above step.

The first conductive layer 21 on the solar cell substrate 46 is electrically connected to the plating power source 40 through a substrate holder 50.

Applying voltage between the positive electrode 47 and the wiring member 3 of the solar cell substrate 46 enables the second conductive layer 22 (copper) to be selectively deposited on the first conductive layer 21 (non-connection portion) that is not coated with the insulation layer 19 in the finger electrode portion 31.

That is, applying voltage between the positive electrode 47 and the wiring member 3 of the solar cell substrate 46 enables copper to be selectively deposited from the holes 23 (openings) generated on the insulation layer 19 by the annealing treatment illustrated in FIG. 5(a) as starting points. The plating step has been described as above.

Back to the description of the production method, a plating solution removing step is provided after the plating step to remove the plating solution 49 remaining on the surface of the solar cell substrate 46.

Then, for example, a lead wire for extracting power to an external circuit is connected to the solar cells 2 as necessary, and the solar cells 2 are sealed by the front surface member 5, the rear surface member 6, and the encapsulant 7 to produce the solar cell module 1.

Next, the detailed structure of the solar cell 2 will be described.

A heterojunction crystal silicon solar cell (hereinafter, also referred to as “heterojunction solar cell”) is employed as the solar cell 2 of the present embodiment.

Specifically, as illustrated in FIG. 7, the solar cell 2 includes the intrinsic silicon-based thin film 16, the conductivity type silicon-based thin film 17, and the transparent electrode layer 18 which are laminated in this order on one surface (the surface on the light incident side, the front surface) of the substrate 15. The solar cell 2 further includes the insulation layer 19 and the collector electrode 8 which are formed on the transparent electrode layer 18.

On the other hand, the intrinsic silicon-based thin film 25, the conductivity type silicon-based thin film 26, and the transparent electrode layer 27 are laminated in this order on the other surface (the surface on the light reflection side, the rear surface) of the substrate 15. The solar cell 2 further includes the rear electrode 28 which is laminated on the transparent electrode layer 27.

That is, the photoelectric conversion section 30 of the solar cell 2 is formed by laminating the transparent electrode layer 27, the conductivity type silicon-based thin film 26, the intrinsic silicon-based thin film 25, the substrate 15, the intrinsic silicon-based thin film 16, the conductivity type silicon-based thin film 17, and the transparent electrode layer 18 in this order from the rear surface side (the second principal surface side) toward the front surface side (the first principal surface side). Further, the intrinsic silicon-based thin films 16 and 25 are respectively interposed between the substrate 15 and each of the conductivity type silicon-based thin films 17 and 26.

The substrate 15 is formed of a one conductivity-type single crystal silicon substrate. Generally, a single crystal silicon substrate includes an n-type single crystal silicon substrate which contains an atom (phosphorus, for example) for introducing an electron in a silicon atom and a p-type single crystal silicon substrate which contains an atom (boron, for example) for introducing a positive hole in a silicon atom.

In this context, “one conductivity-type” indicates either an n type or p type.
That is, the substrate 15 is either an n-type single crystal silicon substrate or a p-type single crystal silicon substrate.
The substrate 15 of the present embodiment is preferably an n-type single crystal silicon substrate.

The substrate 15 has a texture structure in the front surface and the rear surface thereof. That is, the photoelectric conversion section 30 which is formed to have the substrate 15 as a base also has a texture structure.

Thus, the solar cell 2 is capable of trapping incident light in the photoelectric conversion section 30, and therefore has a high power generation efficiency.

The silicon-based thin films 16, 17, 25, and 26 are preferably formed by a plasma CVD method.

Each of the conductivity type silicon-based thin films 17 and 26 is a one conductivity type or an opposite conductivity-type silicon-based thin film.

In this specification, “opposite conductivity-type” indicates a conductivity type that differs from “one conductivity type”.
For example, when “one conductivity type” is an n type, “opposite conductivity-type” is a p type. In the present embodiment, the conductivity type silicon-based thin film 17 is an opposite conductivity-type silicon-based thin film. On the other hand, the conductivity type silicon-based thin film 26 is a one conductivity type silicon-based thin film.

The silicon-based thin film is not particularly limited to any kind as long as it is a silicon-based thin film. However, an amorphous silicon-based thin film is preferably used. In the present embodiment, a p-type amorphous silicon-based thin film is employed as the conductivity type silicon-based thin film 17. On the other hand, an n-type amorphous silicon-based thin film is employed as the conductivity type silicon-based thin film 26.

Each of the intrinsic silicon-based thin films 16 and 25 is preferably an i-type hydrogenated amorphous silicon which is composed of silicon and hydrogen.

As illustrated in FIG. 7, the photoelectric conversion section 30 of the solar cell 2 is provided with the transparent electrode layers 18 and 27 formed on the outer side of the conductivity type silicon-based thin films 17 and 26.

Each of the transparent electrode layers 18 and 27 preferably contains conductive oxide as a main component. Among conductive oxides, each of the transparent electrode layers 18 and 27 more preferably contains indium tin oxide (ITO) as a main component.

In this context, “containing as a main component” indicates that the content is more than 50 wt %, preferably 70 wt % or more, and more preferably 90 wt % or more.

Each of the transparent electrode layers 18 and 27 may be a single layer, or may have a lamination structure which includes a plurality of layers. A doping agent may be added to each of the transparent electrode layers 18 and 27.

The film thickness of the transparent electrode layer 18 on the light incident side is preferably 10 nm or more and 140 nm or less in view of transparency, electrical conductivity, and light reflection reduction.

A role of the transparent electrode layer 18 is transportation of carriers to the collector electrode 8. Thus, the transparent electrode layer 18 having a film thickness of 10 nm or more can have a necessary electrical conductivity.

The transparent electrode layer 18 having a film thickness of 140 nm or less reduces absorption loss in the transparent electrode layer 18. Thus, it is possible to suppress a reduction in the photoelectric conversion efficiency caused by a reduction in the transmittance.

When the film thickness of the transparent electrode layer 18 is within the above range, it is also possible to prevent an increase in the carrier concentration within the transparent electrode layer 18. Thus, a reduction in the photoelectric conversion efficiency caused by a reduction in the transmittance in the infrared region is also suppressed.

A method for forming the transparent electrode layers 18 and 27 is not particularly limited to any method. For example, the transparent electrode layers 18 and 27 may be formed by a sputtering method.

The rear electrode 28 which is located on the outer side of the transparent electrode layer 27 on the second principal surface side with respect to the photoelectric conversion section 30 will be specifically described. As the rear electrode 28, a material that has a high reflectance in the near infrared to infrared range and also has a high electrical conductivity and high chemical stability is desirably used.

Examples of the material satisfying such characteristics include metals such as silver and aluminum. A method for forming the rear electrode 28 is not particularly limited to any method.

When a crystal silicon substrate is used in a heterojunction solar cell as in the solar cell 2 of the present embodiment, the amount of current to be generated is large. Thus, power generation loss caused by the loss of contact resistance between the transparent electrode layer 18 and the collector electrode 8 tends to be remarkable.

On the other hand, in the solar cell module 1 of the present embodiment, the contact resistance between the collector electrode 8 which includes the first conductive layer 21 and the second conductive layer 22 and the transparent electrode layer 18 is low. Thus, it is possible to reduce the power generation loss caused by the contact resistance.

In the solar cell module 1 of the present embodiment, the second conductive layer 22 which has a larger surface roughness than the wiring member 3 is located closest to the front surface member 5 side. The solar cell module 1 includes the surface member 5 on the outer side of the second conductive layer 22. Thus, the solar cell module 1 has a higher photoelectric conversion efficiency than a conventional solar cell module.

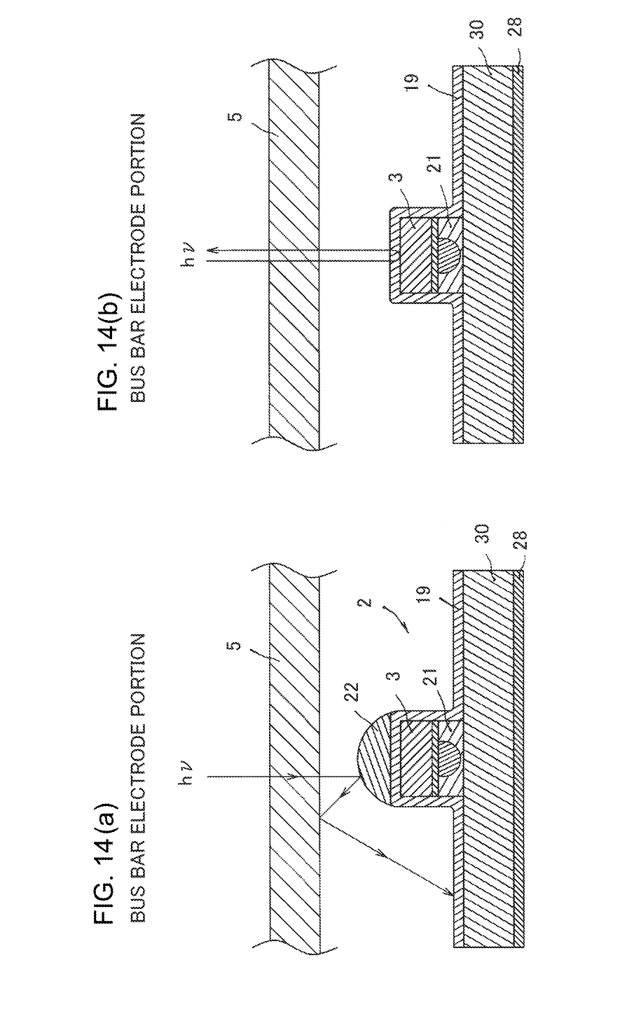

This point will be specifically described with reference to FIGS. 14(a) and 14(b). As illustrated in FIG. 14(a), in the bus bar electrode portion 32 of the present embodiment, light (incident light) that has passed through the front surface member 5 and entered the bus bar electrode portion 32 is reflected by the outer surface of the second conductive layer 22 and directed to the inner surface of the front surface member 5. The light that has been reflected toward the inner surface of the front surface member 5 is reflected because of a difference in refractive index between air and the front surface member 5 and directed to the photoelectric conversion section 30.

On the other hand, when the second conductive layer 22 is not formed in the bus bar electrode portion 32 as in a conventional solar cell module, as illustrated in FIG. 14(b), the incident light that has passed through the front surface member 5 is totally reflected by the surface of the insulation layer 19 or the wiring member 3 and passes through the front surface member 5 so as to escape to the outside.

In this manner, light that has entered from the front surface member 5 is blocked by the wiring member 3 in a conventional solar cell module. On the other hand, most part of the incident light from the front surface member 5 can be collected in the photoelectric conversion section 30 in the solar cell module 1 of the present embodiment.

Although the insulation layer forming step is performed after the wiring member bonding step in the first embodiment described above, the present invention is not limited thereto. The insulation layer forming step may be performed before the wiring member bonding step. As an example thereof, a solar cell module 80 of a second embodiment will be described. Similar elements as those of the first embodiment will be designated by the same reference numerals, and description thereof will be omitted.

A solar cell 81 which is built in the solar cell module 80 of the second embodiment differs from the solar cell 2 of the first embodiment in the lamination structure in a bus bar electrode portion 82.

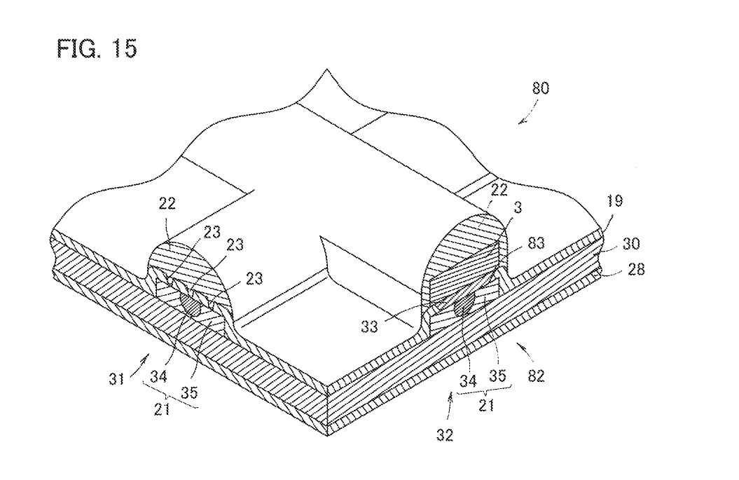

Specifically, as can be seen from FIG. 15, the bus bar electrode portion 82 of the solar cell 81 includes a photoelectric conversion section 30, a first conductive layer 21 which is stacked on the photoelectric conversion section 30, and an insulation layer 19 which is formed to cover the surface of the first conductive layer 21. A wiring member 3 is located on the outer side of the insulation layer 19 with respect to the photoelectric conversion section 30. An adhesive material 33 having electrical conductivity is interposed between the first conductive layer 21 and the wiring member 3.

A through hole 83 is formed on the insulation layer 19 in addition to the holes 23 of the first embodiment.

The through hole 83 is a hole which penetrates the insulation layer 19 in the thickness direction thereof. The through hole 83 is used for electrically connecting the first conductive layer 21 and the wiring member 3 to each other.

The through hole 83 is filled with the adhesive material 33. The first conductive layer 21 is electrically connected to the wiring member 3 through the through hole 83 of the insulation layer 19.

Next, a method for producing the solar cell module 80 of the present embodiment will be described. In particular, a collector electrode 8 will be specifically described.

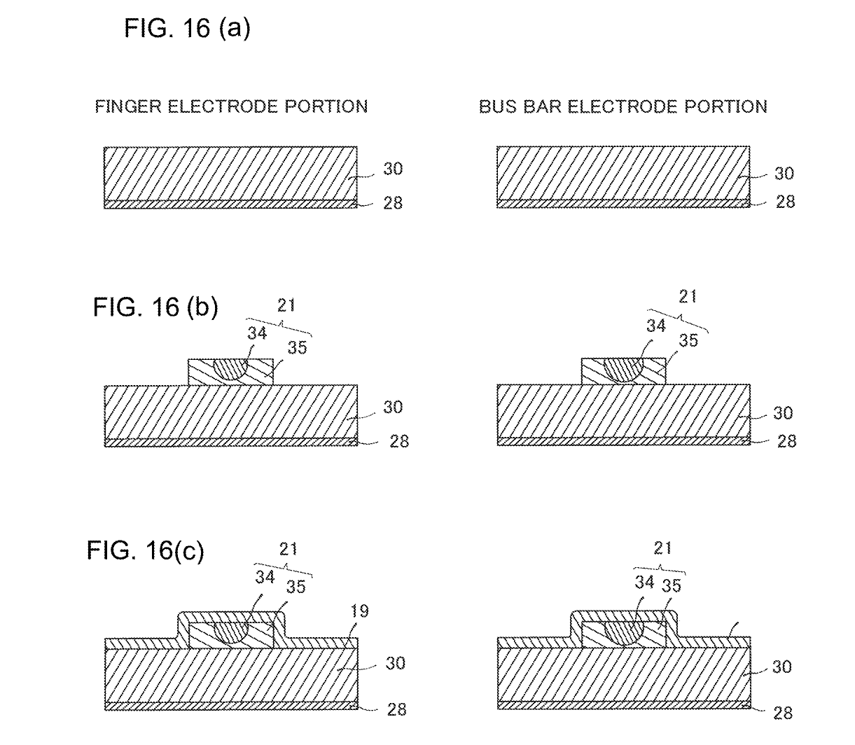

The same steps as those in the method for producing the solar cell module 1 of the first embodiment will be briefly described. Further, the description will be made by focusing the bus bar electrode portion 82 and the vicinity thereof. FIGS. 16(a) to (c) and 17(d) to (f) are explanatory diagrams of the method for producing a finger electrode portion 31, the bus bar electrode portion 82, and the vicinities thereof.

As illustrated in FIG. 16(a), the photoelectric conversion section 30 is first formed in a photoelectric conversion section preparing step.

Then, in a first conductive layer forming step, the first conductive layer 21 is formed on the outer side of the photoelectric conversion section 30 by a screen printing method as illustrated in FIG. 16(b).

Then, as illustrated in FIG. 16(c), the insulation layer 19 is formed on the first conductive layer 21 (an insulation layer forming step). That is, the insulation layer 19 is formed prior to a wiring member bonding step in the method for producing the solar cell module 80 of the second embodiment.

At this point, the insulation layer 19 may be formed only on the first conductive layer 21 in a first conductive layer forming region 37, or may be formed also on the photoelectric conversion section 30 in a first conductive layer non-forming region 38 in the bus bar electrode portion 82.

In the present second embodiment, the insulation layer 19 is formed on the entire one principal surface side (first principal surface side) of the photoelectric conversion section 30.

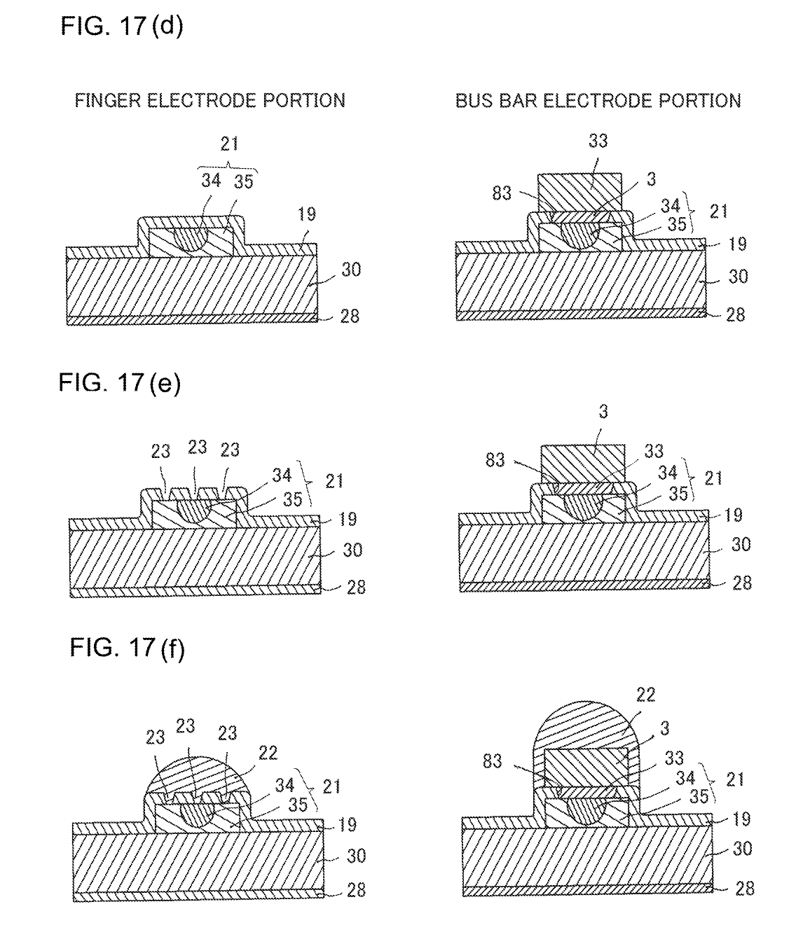

After the insulation layer forming step, as illustrated in FIG. 17(d), the wiring member 3 is placed on the first conductive layer 21 within the bus bar electrode portion 82, and thermocompression-bonded thereto with the adhesive material 33 (a wiring member bonding step).

At this point, the insulation layer 19 is interposed between the wiring member 3 and the first conductive layer 21. A part of the insulation layer 19 is peeled off by the thermocompression bonding, so that the through hole 83 is formed. Then, the through hole 83 is filled with the adhesive material 33, so that the wiring member 3 and the first conductive layer 21 are electrically connected to each other through the adhesive material 33.

After the wiring member bonding step, as illustrated in FIG. 17(e), an annealing step is performed to heat the substrate on which the wiring member 3 is placed at an annealing temperature Ta so as to anneal.

At this point, the holes 23 are formed on the insulation layer 19 in the finger electrode portion 31.

After the annealing step, as illustrated in FIG. 17(f), the second conductive layer 22 is formed on the insulation layer 19 in the first conductive layer forming region 37 by a plating method (a plating step).

At this point, the second conductive layer 22 is deposited on the surface of the wiring member 3. Thus, the outer surface of the wiring member 3 is roughened. Further, a part of the wiring member 3 in the bus bar electrode portion 82 is buried in the second conductive layer 22.

Then, a plating solution removing step is performed as necessary. Then, for example, a lead wire for extracting power to an external circuit is connected to the solar cells 81. Then, the solar cells 81 are sealed by a front surface member 5, a rear surface member 6, and a encapsulant 7. The solar cell module 80 is thus produced.

Although only the collector electrode 8 as a front side electrode is provided by an electrolytic plating method in the above embodiment, the present invention is not limited thereto. For example, when metal electrodes are formed on both the first principal surface and the second principal surface of the solar cell, a front side electrode (the second conductive layer 22, for example) and a rear side electrode (the rear electrode 28, for example) may be formed by an electrolytic plating method.

In view of simplifying the production process, the front side electrode and the rear side electrode are preferably simultaneously formed.

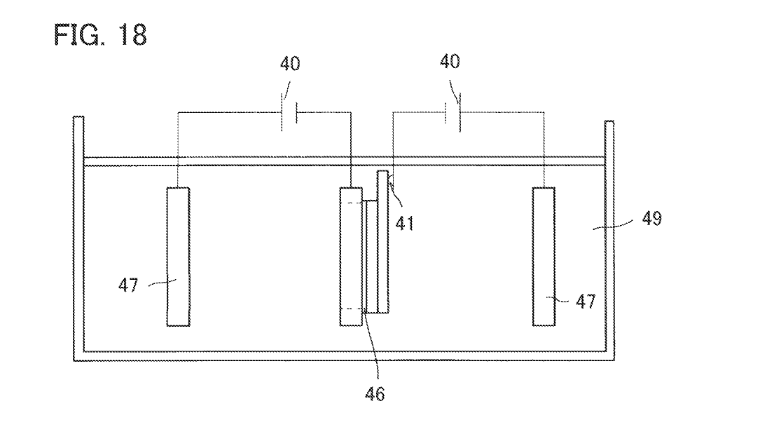

Specifically, as illustrated in FIG. 13(c), electrode contacts (feeding points 41) are provided in two side directions so that current flows to both the front surface and the rear surface of the solar cell substrate 46. Further, as illustrated in FIG. 18, positive electrodes 47 are disposed to face both the front surface (first principal surface) and the rear surface (second principal surface) of the solar cell 2. Then, voltage is applied to these electrodes 47. Accordingly, it is possible to simultaneously plate both the front surface and the rear surface of the solar cell substrate 46. In this case, plating is preferably performed in a manner to have a common potential between the front surface and the rear surface of the solar cell substrate 46 so that wiring can be simplified.

As a method for plating both the front surface and the rear surface of the solar cell substrate 46, wiring members 3 are bonded to both the front surface and the rear surface of the solar cell substrate 46. Then, power is preferably supplied to the surfaces of the solar cell substrate 46 to be plated through the wiring members 3.

After adjacent solar cells 2 are connected to each other through the wiring members 3 before the plating step, the solar cells 2 are introduced into a plating apparatus. Then, power is supplied from the plating power source 40 to the surfaces to be plated (the first conductive layers 21 of the finger electrode portions 31, for example). Accordingly, it is possible to simultaneously form second conductive layers 22 of a plurality of the solar cells 2.

At this point, as illustrated in FIG. 13(c), the feeding point 41 to have contact with the electrode contact of the plating power source 40 is preferably provided for each wiring member 3 in view of improving uniformity of line width and film thickness of the second conductive layer 22.

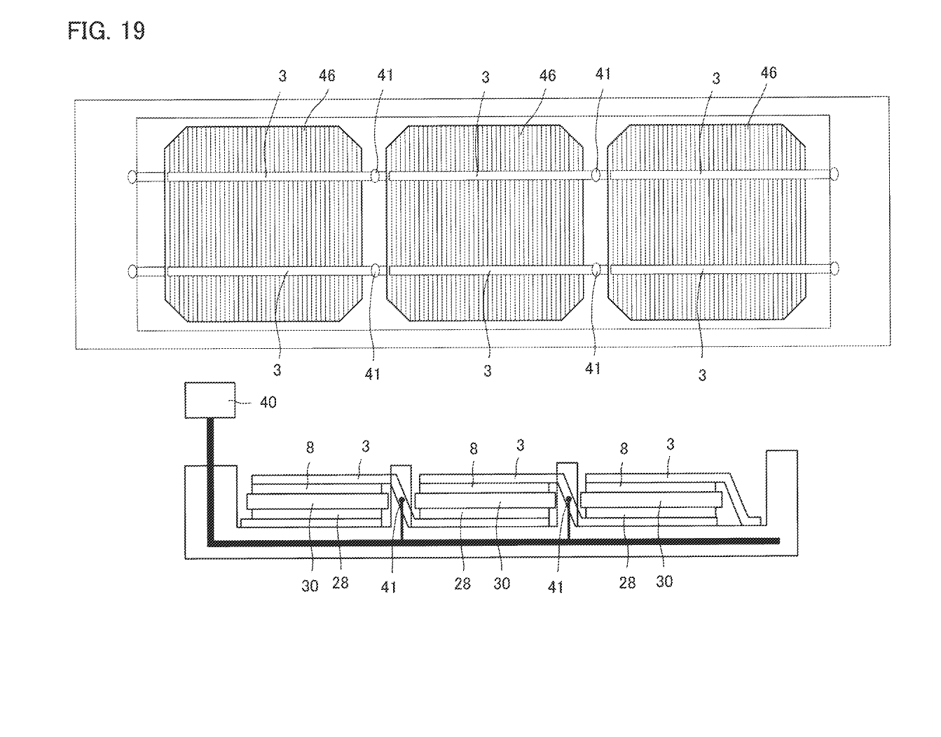

Further, it is also possible to use a jig schematically illustrated in FIG. 19 in the production of the solar cell module 1. Specifically, a jig that has an uneven structure such as a counterbore or a position adjustment mechanism such as a backing plate may be used in the production of the solar cell module 1.

Using the jig enables accurate alignment between the feeding point 41 on the wiring member 3 located between the solar cells 2, 2 and the electrode contact disposed on the jig. Further, using the jig also enables electrical connection in the connection point between the wiring member 3 and the jig to be reliably achieved.

Further, using the jig makes it possible to convey the solar cell 2 as being placed on the jig. Thus, it is also possible to prevent damage of the solar cell 2 during the conveyance.

When a film forming surface (a surface on which the second conductive layer 22 is to be formed) of the solar cell substrate 46 is covered with the jig in the plating step of forming the second conductive layer 22, the second conductive layer 22 may not be sufficiently formed on the portion covered with the jig.

In order to prevent such a phenomenon, as illustrated in FIG. 19, the distance width of the jig located between adjacent solar cells 2, 2 is preferably substantially equal to or smaller than the distance between the solar cells 2, 2.

In particular, when the solar cell substrate 46 which has circular arc four corners is used, the above phenomenon can be prevented also by arranging the feeding point 41 of the wiring member 3 at a position near one side of the solar cell substrate 46.

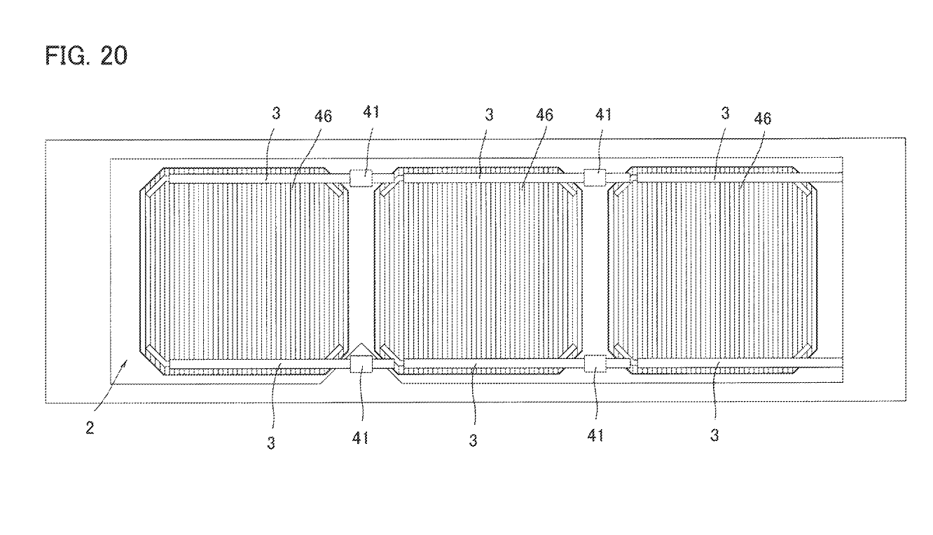

In this case, as illustrated in FIG. 20, a sufficient alignment accuracy of the electrode contact and a sufficient mechanical strength of the jig may be achieved.

When the electrode layer on the font surface (the rear electrode 28, for example) and the electrode layer on the rear surface (the first conductive layer 21, for example) are electrically short-circuited on the outer periphery of the solar cell substrate 46, insulation treatment is preferably performed before the bonding of the wiring member 3.

After the plating step, the material of the second conductive layer 22 may be deposited on the contact point between the wiring member 3 and the jig. The deposited material of the second conductive layer 22 may increase the contact resistance in the contact point of the wiring member 3. Accordingly, as described above, cleaning is preferably performed after the plating step to remove the metal material deposited on the contact point of the wiring member 3.

In particular, when the plating is performed on a plurality of solar cells 2 using the same plating bath as described above, a difference in contact resistance in the contact point between the wiring member 3 and the jig may cause variation in the film thickness or line width of the second conductive layer 22. Thus, it is more preferred to clean the contact point after the plating step.

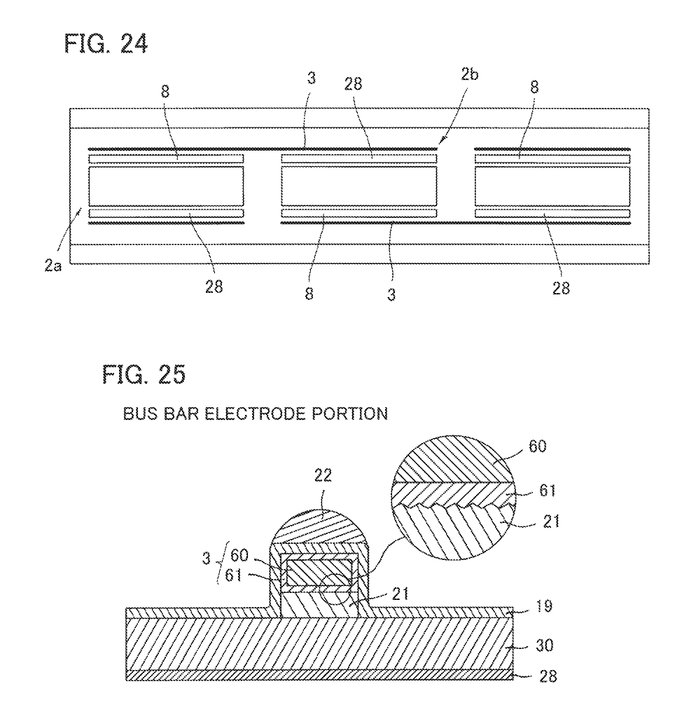

In the above embodiment, when one solar cell 2a is connected to a solar cell 2b adjacent thereto through a wiring member 3, the solar cell 2a and the adjacent solar cell 2b face in the same direction. However, the present invention is not limited thereto. As illustrated in FIG. 24, the posture of the solar cell 2a may be upside down with respect to the solar cell 2b adjacent thereto.

That is, the front and rear may be reversed between the solar cell 2a and the solar cell 2b. In this case, it is not necessary to route the wiring member 3 from the first principal surface to the second principal surface of the solar cells 2 when the solar cells 2a and 2b are connected in series. Thus, it is possible to easily connect the solar cells 2a and 2b.

Although the entire surface to be bonded of the wiring member 3 and the first conductive layer 21 are bonded to each other in the above embodiment, the present invention is not limited thereto. The entire surface to be bonded of the wiring member 3 and the first conductive layer 21 may not necessarily be bonded to each other.

That is, the first conductive layer 21 may not necessarily have the bus bar electrode portion 32. Further, the first conductive layer 21 may have a shape including an opening, a notched portion, or a gap.

Although the first conductive layer 21 which includes a plurality of finger electrode portions 31 and a plurality of bus bar electrode portions 32 is used in the above embodiment, the present invention is not limited thereto. The configuration of the first conductive layer 21 is not particularly limited to any configuration.

For example, the first conductive layer may be a so-called bus bar less electrode which includes only a plurality of finger electrode portions 31 and includes no bus bar electrode portion 32.

The first conductive layer 21 may be formed on a light transmissive conductive film which is formed to be in contact with the light receiving surface of the photoelectric conversion section 30. In this case, the light transmissive conductive film may be composed of a light transmissive conductive oxide such as indium tin oxide (ITO) and zinc oxide (ZnO).

In the above embodiment, the rear electrode 28 of one solar cell 2 is connected to the bus bar electrode portion 32 of another solar cell 2 through the wiring member 3, for example, a tab in modularization of the solar cells 2. Accordingly, a plurality of solar cells 2 are connected in series or parallel. Then, the connected solar cells 2, 2 are sealed by the front surface member 5, the rear surface member 6, and the encapsulant 7 to perform the modularization. However, the present invention is not limited thereto.

For example, as described above, a single solar cell 2 may be used. Also in this case, the solar cell 2 is called a solar cell module as described above.

In the above embodiment, the low melting point material 34 and the high melting point material 35 are combined as the material of the first conductive layer 21 to thereby form the holes 23 (openings). However, the present invention is not limited thereto.

That is, a method for forming the holes 23 is not particularly limited to any method. The holes 23 (openings) may be formed by methods such as masking, laser radiation, mechanical boring, and chemical etching. In this case, only the high melting point material 35 may be used.

In the above embodiment, the holes 23 of the insulation layer 19 are formed using a change in the properties of the first conductive layer 21 at the annealing temperature, and the second conductive layer 22 is formed thereon to form the collector electrode 8. However, the present invention is not limited thereto.

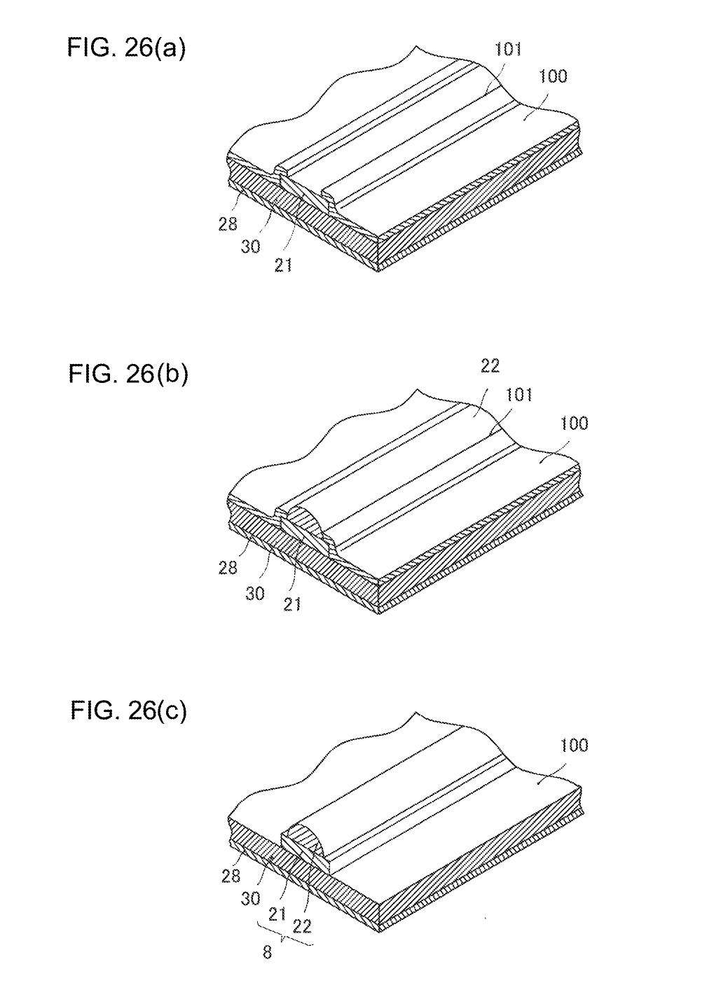

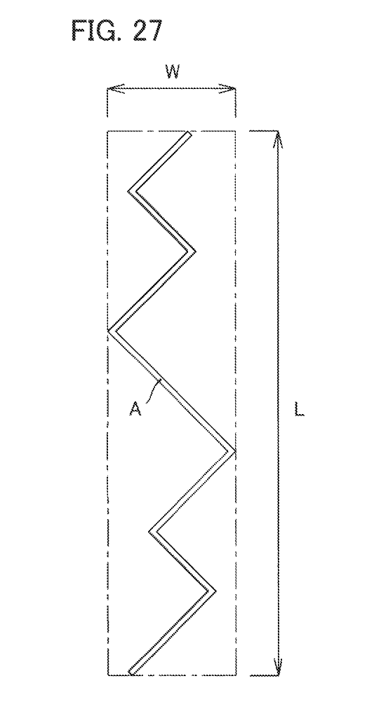

For example, the collector electrode 8 may be formed in the following manner. A hole 101 (opening) is previously formed using a resist layer 100 such as a photoresist in the insulation layer forming step as illustrated in FIG. 26(a), and the second conductive layer 22 is formed in the plating step as illustrated in FIG. 26(b). Then, as illustrated in FIG. 26(c), the resist layer 100 is peeled off.

Further, metal fine particles each having a particle diameter of 1 μm or less may be used as the material of the first conductive layer 21. Specifically, metal fine particles in the nano-order may cause sintering/necking (fusion of the fine particles) when the temperature thereof becomes lower than the melting point. Thus, the fine particles are heated at a temperature that is equal to or higher than a sintering/necking starting temperature T1′ as well as equal to or lower than the melting point T1 to cause deformation in the vicinity of the outer peripheries of the fine particles. Accordingly, it is possible to change the surface shape of the first conductive layer 21 to form the holes 23 on the insulation layer 19.

For example, the size (the particle diameter, for example) of the material may be adjusted to prevent disconnection of the first conductive layer 21 caused by heating in the annealing step and improve the conversion efficiency.

Specifically, even a material having a high melting point such as silver, copper, and gold may cause sintering/necking (fusion of fine particles) at approximately 200° C. which is lower than the melting point or at the temperature T1′ which is equal to or lower than 200° C. when the material is in the form of fine particles having a particle diameter of 1 μm or less. Thus, the material having a high melting point such as silver, copper, and gold may also be used as the low melting point material 34.

Such a material that causes sintering/necking may cause deformation in the vicinity of the outer peripheries of fine particles when being heated to the sintering/necking starting temperature T1′ or higher. Thus, it is possible to change the surface shape of the first conductive layer 21 to form the holes 23 on the insulation layer 19.

Further, when fine particles are heated to the sintering/necking starting temperature or higher, but lower than the melting point T2′, the fine particles are maintained in a solid phase state. Thus, disconnection resulting from enlargement of the material is not likely to occur. That is, the material that causes sintering/necking such as metal fine particles or the like serves as not only the low melting point material 34, but also the high melting point material 35.

In such a material that causes sintering/necking, the sintering/necking starting temperature T1′=the heat flow starting temperature T1 can be defined.

When it is difficult to strictly measure the sintering/necking starting temperature, the first conductive layer 21 containing fine particles is formed, the insulation layer 19 is formed on the first conductive layer 21, and a temperature at which the holes 23 (cracks) are generated on the insulation layer 19 by heating may be regarded as the sintering/necking starting temperature.

When heating is performed to form the insulation layer 19, a temperature at which the holes 23 (cracks) are generated by heating the substrate when the insulation layer 19 is formed may be regarded as the sintering/necking starting temperature.

Although the step of attaching the wiring member 3 to the solar cell 2 has been described in the above embodiment, the present invention is not limited thereto. For example, when the solar cell module 1 which includes a plurality of solar cells 2 is produced, as illustrated in FIG. 19, the second conductive layer 22 may be formed after a wiring member 3 bonded to one solar cell substrate 46 is bonded to another solar cell substrate 46. Such a method enables the productivity to be improved.

Although the second conductive layer 22 is formed of a single layer in the above embodiment, the present invention is not limited thereto. The second conductive layer 22 may include a plurality of layers.

For example, as the second conductive layer 22, a first plating layer which is made of a material having a high electrical conductivity such as copper (Cu) is formed on the first conductive layer 21 with the insulation layer 19 interposed therebetween, and a second plating layer having excellent chemical stability is then formed on the surface of the first plating layer.

Accordingly, the second conductive layer 22 has a multilayer structure in which the second plating layer is stacked on the first plating layer. Thus, it is possible to form the collector electrode 8 having a low resistance and excellent chemical stability.

Although the solar cell module 1 is used with being coated with the insulation layer 19 as it is in the present embodiment, the present invention is not limited thereto. An insulation layer removing step may be performed after the formation of the collector electrode (after the plating step).

In particular, when a material having a high light absorption is used as the insulation layer 19, the insulation layer removing step is preferably performed in order to suppress deterioration of the photoelectric characteristics of the solar cell caused by the light absorption by the insulation layer 19.

In this case, in view of further improving the light taking-in effect, the insulation layer 19 on the first conductive layer non-forming region 38 is preferably totally removed.

In the above embodiment, a heterojunction solar cell is used as the solar cell 2, and the collector electrode 8 is disposed on the light incident side (first principal surface side). However, the present invention is not limited thereto. A similar collector electrode may be formed also on the rear surface side (the side opposite to the light incident side).

In the above embodiment, a heterojunction crystal silicon-based solar cell is used as the solar cell 2. However, the present invention is not limited thereto. The solar cell 2 may be another kind of solar cell. For example, the solar cell 2 may be formed of a crystal semiconductor wafer such as a single crystal silicon wafer and a polycrystal silicon wafer.

In this case, a crystal semiconductor wafer to be used preferably has a generally square shape. The average thickness of the crystal semiconductor wafer is preferably 0.05 mm or more and 0.15 mm, and more preferably 0.1 mm or more and 0.2 mm or less.

With the crystal semiconductor wafer being set within such a range, it is possible to form a thin solar cell while ensuring a function as a substrate and a sufficient strength.

With the crystal semiconductor wafer being set within such a range, the average thickness becomes relatively thin. Thus, the crystal semiconductor wafer is likely to be broken by, for example, pressing. However, it is possible to perform film formation without damage by using the production method of the above embodiment.

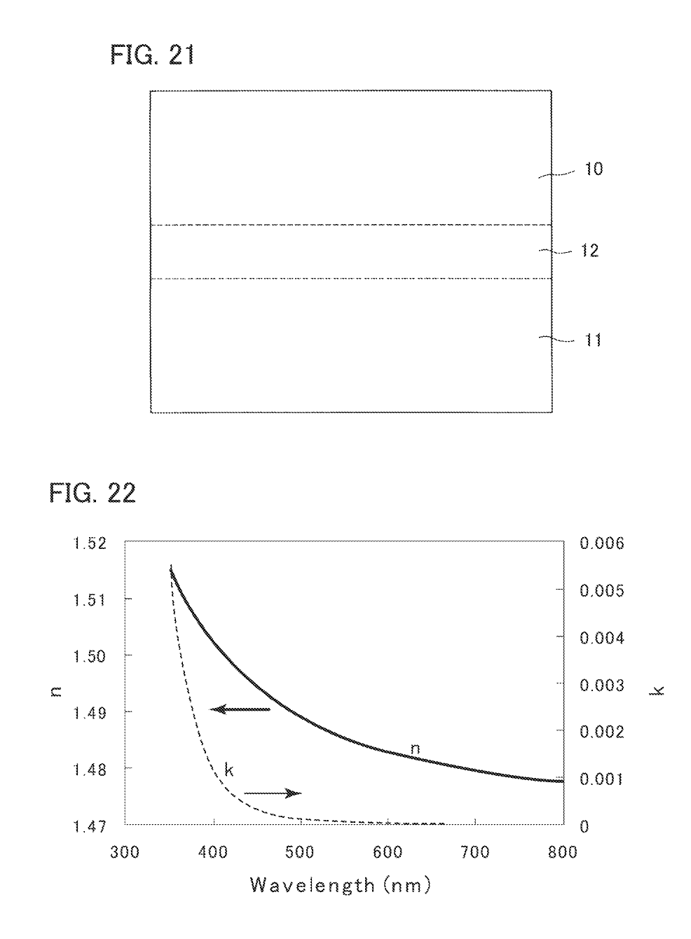

As illustrated in FIG. 21, the solar cell 2 includes an n-type semiconductor region 10 and a p-type semiconductor region 11 in a lamination direction. A semiconductor joint portion 12 is formed on the interface between the n-type semiconductor region 10 and the p-type semiconductor region 11.

The n-type semiconductor region 10 and the p-type semiconductor region 11 may be composed of crystal semiconductors or amorphous semiconductors.

Even such a solar cell that has a thinned wafer makes it possible to prevent damage caused by pressing from a connection terminal of the plating power source 40 by arranging the feeding point connected from the plating power source 40 on the wiring member 3 in the plating step as in the above embodiment.

In addition to such a solar cell, there may be used a solar cell that includes a substantially intrinsic amorphous silicon layer interposed between a single crystal silicon substrate and an amorphous silicon layer to reduce a defect on the interface between the single crystal silicon substrate and the amorphous silicon layer and improve the characteristics of a heterojunction interface.

Further, various types of solar cells such as crystal silicon solar cells except a heterojunction solar cell, solar cells in which a semiconductor substrate other than a silicon substrate, for example, a GaAs substrate is used, silicon-based thin film solar cells in which a transparent electrode layer is formed on pin junction or pn junction of amorphous silicon-based thin films or crystal silicon-based thin films, compound semiconductor solar cells such as a CIS solar cell and a CIGS solar cell, dye sensitized solar cells, organic thin film solar cells made of an organic thin film (conductive polymer) may be applicable to the solar cell of the present invention.

In the above embodiment, the wiring member 3 is connected after the adhesive material 33 is applied onto the first conductive layer 21. However, the present invention is not limited thereto. The adhesive material 33 may be previously formed on the surface of the wiring member 3.

For example, a wiring member on which a solder material is previously formed may be used, and the wiring member may be bonded to the surface of the solar cell 2.

In the above first and second embodiments, the second conductive layer 22 is stacked on the wiring member 3 with the insulation layer 19 partially or entirely interposed therebetween in the bus bar electrode portion 32. However, the present invention is not limited thereto.

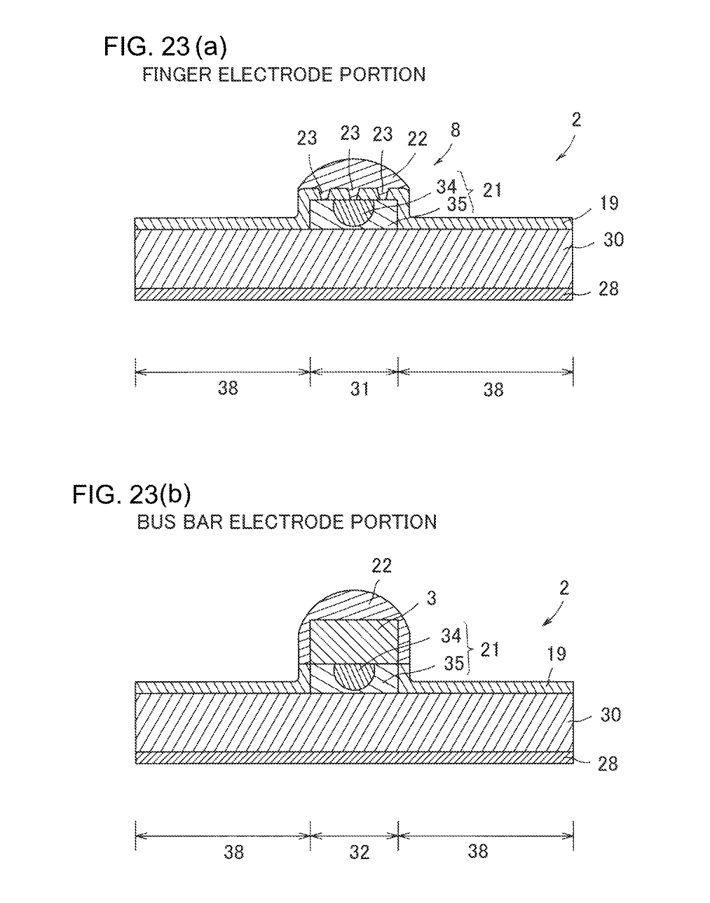

As illustrated in FIG. 23(b), the insulation layer 19 may not be interposed between the wiring member 3 and the second conductive layer 22. In this case, the plating step is preferably performed without forming the insulation layer 19 on the surface of the wiring member 3.

In the above embodiment, the wiring member 3 is bonded onto the first conductive layer 21 using the adhesive material 33 which is a separate body from the wiring member 3 in the wiring member bonding step. However, the present invention is not limited thereto.

When the wiring member 3 whose surface is previously coated with the adhesive material 33 is used, it is not necessary to again apply the adhesive material 33 in the wiring member bonding step. That is, when the coating layer 61 of the wiring member 3 is formed of the adhesive material 33, it is not necessary to again interpose the adhesive material 33 between the wiring member 3 and the first conductive layer 21. In other words, the adhesive material 33 may be previously adhered to the surface of the wiring member 3 as coating in the wiring member bonding step.

In the above embodiment, the adhesive material 33 is interposed between the first conductive layer 21 and the wiring member 3 in the bus bar electrode portion 32. However, the present invention is not limited thereto. The wiring member 3 may be directly bonded onto the first conductive layer 21.

In this case, it is preferred that the coating layer 61 which is softer than the first conductive layer 21 be employed, asperities be formed on the surface of the first conductive layer 21, and the first conductive layer 21 and the wiring member 3 be pressure bonded to each other. That is, as illustrated in FIG. 25, the projections of the first conductive layer 21 are preferably allowed to bite into the coating layer 61 of the wiring member 3. This enables the wiring member 3 to be unlikely to be displaced with respect to the first conductive layer 21.

As a method for forming the asperities, for example, the asperities may be formed by processing the surface by etching or the like, or directly formed by a plating method or the like. As an example of the formation by a plating method, plating is performed in such a manner that components of a plating solution are adjusted so that the plating surface is roughened in a needle shape.

In the above embodiment, the second conductive layer 22 having a lower electrical resistance than the first conductive layer 21 is used. However, the present invention is not limited thereto. The second conductive layer 22 has only to have a resistance equal to or lower than the electrical resistance of the first conductive layer 21.

In the above embodiment, the intrinsic silicon-based thin films 16 and 25 are respectively formed between the substrate 15 and each of the conductivity type silicon-based thin films 17 and 26. However, the present invention is not limited thereto. The intrinsic silicon-based thin films 16 and 25 may not necessarily be provided.

Hereinafter, the present invention will be more specifically described using examples. However, the present invention is not limited to these examples.

### EXAMPLES

Manufacturing procedures of solar cells and solar cell modules of specific examples of the present invention and comparative examples with respect to the examples and evaluation results thereof will be described.

### Example 1

A heterojunction solar cell of Example 1 was produced in the following manner.

As a one conductivity type single crystal silicon substrate that serves as the substrate 15, a generally square n-type single crystal silicon wafer having a plane orientation of the incident surface of (100), a thickness of 200 μm, and 6 inches (156 mm) square was used. The silicon wafer was immersed in a hydrofluoric acid (HF) aqueous solution of 2 wt % for 3 minutes to remove a silicon oxide film on the surface thereof. Then rinsing with ultrapure water was performed twice. Then, the silicon substrate was immersed in a potassium hydroxide (KOH)/isopropyl alcohol aqueous solution of 5/15 wt % maintained at 70° C. for 15 minutes to etch the surface of the wafer to thereby form a texture structure. Then, rinsing with ultrapure water was performed twice.

The surface of the wafer was observed using an atomic force microscope (AFM manufactured by Pacific nanotechnology, Inc.). As the result, the surface of the wafer was most etched, and a pyramid-shaped texture having an exposed (111) surface was formed thereon.

The etched wafer was introduced into a CVD apparatus. As the intrinsic silicon-based thin film 16, an i-type amorphous silicon layer was formed on the light incident side of the wafer so as to have a film thickness of 5 nm. Conditions for forming the i-type amorphous silicon layer were a substrate temperature of 150° C., pressure of 120 Pa, SiH₄/H₂ flow rate ratio of 3/10, and input power density of 0.011 W/cm². The thickness of the thin film in the present example is a value that is calculated from a film formation rate obtained by measuring the thickness of a thin film formed on a glass substrate under the same conditions as the above conditions using a spectroscopic ellipsometry (product name: M2000, manufactured by J. A. Woollam Co., Inc.).

As an opposite conductivity-type silicon-based thin film which serves as the conductivity type silicon-based thin film 17, a p-type amorphous silicon layer was formed on the i-type amorphous silicon layer so as to have a film thickness of 7 nm. Conditions for forming the p-type amorphous silicon layer were a substrate temperature of 150° C., pressure of 60 Pa, SiH₄/B₂H₆ flow rate ratio of 1/3, and input power density of 0.01 W/cm². The B₂H₆ gas flow rate is a flow rate of diluent gas diluted by H₂ up to a B₂H₆ concentration of 5000 ppm.

Then, as the intrinsic silicon-based thin film 25, an i-type amorphous silicon layer was formed on the rear surface side of the wafer so as to have a film thickness of 6 nm. Conditions for forming the i-type amorphous silicon layer were the same as the conditions for forming the above i-type amorphous silicon layer. Then, as the conductivity type silicon-based thin film 26, an n-type amorphous silicon layer was formed on the i-type amorphous silicon layer so as to have a film thickness of 4 nm. Conditions for forming the n-type amorphous silicon layer were a substrate temperature of 150° C., pressure of 60 Pa, SiH₄/PH₃ flow rate ratio of 1/2, and input power density of 0.01 W/cm². The PH₃ gas flow rate is a flow rate of diluent gas diluted by H₂ up to a PH₃ concentration of 5000 ppm.

An indium tin oxide (ITO, refractive index: 1.9) layer was formed on the above layer so as to have a film thickness of 100 nm as each of the transparent electrode layer 18 on the light incident side and the transparent electrode layer 27 on the rear surface side. The transparent electrode layers 18 and 27 were formed using indium oxide as a target while applying a power density of 0.5 W/cm² at a substrate temperature of room temperature and a pressure of 0.2 Pa in an argon atmosphere.

A silver layer was formed, as the rear electrode 28, on the transparent electrode layer 27 by a sputtering method so as to have a film thickness of 500 nm. The collector electrode 8 which includes the first conductive layer 21 and the second conductive layer 22 was formed on the transparent electrode layer 18 in the following manner.

The first conductive layer 21 was formed using a printing paste that includes tin-bismuth (SnBi) metal powder (the particle diameter D_{L}=25 to 35 μm, the melting point T1=141° C.) as the low melting point material 34 and silver powder (the particle diameter D_{H}=12 to 3 μm, the melting point T2=971° C.) as the high melting point material 35 at a weight ratio of 20:80, and further includes an epoxy resin as a binder resin. The printing paste was screen-printed using a screen printing plate of #230 mesh (the opening width: 1=85 μm) having an opening width (L=80 μm) corresponding to a collector electrode pattern and dried at 90° C.

The forming region of the first conductive layer 21 includes the bus bar electrode portions 32 and the finger electrode portions 31. The width of the bus bar electrode portions 32 was 1.5 mm. The line width of the finger electrode portions 31 was 105 μm. The distance between the finger electrode portions 31 was 2 mm.

The wafer having the first conductive layer 21 formed thereon was put into a CVD apparatus, and a silicon oxide layer (the refractive index: 1.5) was formed, as the insulation layer 19, on the light incident surface side by a plasma CVD method so as to have a thickness of 80 nm.

Conditions for forming the insulation layer 19 were a substrate temperature of 135° C., pressure of 133 Pa, SiH₄/CO₂ flow rate ratio of 1/20, and input power density of 0.05 W/cm² (frequency 13.56 MHz).

The refractive index (n) and the extinction coefficient (k) of the insulation layer 19 formed on the light incident surface side under the above conditions were as illustrated in FIG. 22.

Then, the wafer on which the insulation layer 19 has been formed was introduced into a hot air circulation type oven, and annealing treatment was performed at 180° C. for 20 minutes in the atmosphere.

Then, the silicon wafer on the cell outer periphery was removed by a width of 0.5 mm using a laser beam machine to remove an electric short-circuit portion between the front surface (first principal surface side) and the rear surface (second principal surface side).

The wiring member 3 made of copper foil having a width of 1.5 mm, thickness of 0.2 mm, and length of 155 mm was bonded onto the first conductive layer 21 in the bus bar electrode portion 32 using a conductive film having a width of 1.2 mm and a length of 152 mm. Specifically, the wiring member 3 was placed on the first conductive layer 21 and bonded thereto by thermocompression bonding.

At this point, the wiring member 3 was bonded in a manner to allow one end of the wiring member 3 to be arranged at a position 1.5 mm away from the end of the silicon substrate. The conductive film was used in the bonding of the wiring member 3. A contact point to have contact with a plating electrode side feeding point was arranged at a position 1.5 mm away from the other end of the wiring member 3.

The solar cell substrate 46 to which the wiring member 3 has been bonded in the above manner was put into the plating bath 48 as illustrated in FIG. 12. The contact point to have contact with the plating power source 40 was arranged on the wiring member 3 in a region that is not bonded to the solar cell substrate 46 (silicon substrate). In other words, the contact point to have contact with the plating power source 40 was located at a position other than the connection region between the solar cell substrate 46 and the wiring member 3.

As the plating solution 49, a solution prepared to contain copper sulfate penta-hydrate in concentration of 120 g/l, sulfuric acid in concentration of 150 g/l, and sodium chloride in concentration of 70 mg/l with an additive (item number: ESY-2B, ESY-H, ESY-1A manufactured by C. Uyemura & Co., Ltd.) was used.

Plating was performed using this plating solution under a condition of a temperature of 40° C. and current of 3 A/dm². Copper having a thickness of approximately 10 μm was uniformly deposited as the second conductive layer 22 on the insulation layer 19 on the first conductive layer 21. Generally, deposition of copper on a region in which the first conductive layer 21 is not formed was rarely confirmed.

Then, the substrate on which the second conductive layer 22 has been formed was washed with water to remove the plating solution 49 adhered to the surface thereof. At this point, the line resistivity of the bus bar electrode portion 32 was measured, and the result thereof was 1 Ω/cm.

### Example 2

A solar cell was manufactured in the same manner as in Example 1 except that the ratio between tin-bismuth (SnBi) metal powder and silver powder is 60:40 and the line resistivity of the bus bar electrode portion 32 became 10 Ω/cm.

### Example 3

A solar cell was manufactured in the same manner as in Example 1 except that the collector electrode 8 was a collector electrode having a so-called bus bar less structure in which the first conductive layer 21 of the bus bar electrode portion 32 is not provided.

### Example 4

Four solar cells 2 in process on each of which the first conductive layer 21 is formed were prepared in the method described in Example 1, and the four solar cells 2 were arranged on a straight line with the p-type amorphous silicon surfaces facing upward. Then, the front surface and the rear surface of each of the adjacent solar cells 2 were connected to each other by the wiring member 3 so that the four solar cells 2 are electrically connected in series.

In the solar cell 2 located on each end in the parallel direction, that is, the solar cell 2 that has an adjacent solar cell 2 only on one side thereof, a lead wire for extracting power to an external circuit was bonded to the non-bonded surface of the wiring member 3 connected to the adjacent solar cell 2. At this point, the length of the wiring member 3 was 310 mm, and the interval between the adjacent solar cells 2 (the distance between the adjacent solar cells 2, 2) was 2 mm.

Then, electrolytic plating was performed using a region located between the solar cell substrates 46, 46 in the wiring member 3, that is, a portion that is not bonded to the solar cell substrates 46 as illustrated in FIG. 19 as the feeding point 41.

At this point, the series of solar cell substrates 46 connected by the wiring members 3 was immersed in a plating bath filled with a copper sulfate plating solution. In this immersed state, energization was performed at the feeding points 41 connected from the plating power source 40 to allow copper to be deposited on the first conductive layers 21 and the rear electrodes 28. Then, water washing was performed to remove the plating solution adhered to the surfaces thereof. The lead wires connected to the external circuit were connected to the series of the solar cells 2, specifically, the solar cells 2 on the opposite ends after the plating. Then, the solar cells were sandwiched between a glass substrate (the front surface member 5) and a rear sheet (the rear surface member 6) and sealed by filling a sealing agent (the encapsulant 7) therein. Then, the lead wires were attached to a wiring box to manufacture the solar cell module 1.

### Comparative Example 1

A solar cell 2 was manufactured in the same manner as in Example 1 except that a feeding point connected from a plating power source was arranged on an end of a first conductive layer 21 of each bus bar electrode portion 32 to form a second conductive layer 22, and a wiring member 3 was then bonded onto the second conductive layer 22.

### Comparative Example 2

A solar cell was manufactured in the same manner as in Comparative Example 1 except that the material used in Example 2 was used as the material of the first conductive layer 21.

### Comparative Example 3

A solar cell module 1 was manufactured in such a manner that four solar cells 2 manufactured in the same manner as in Comparative Example 1 were prepared, and electrically connected in series by wiring members 3 in the same manner as in Example 4.

The line resistance of the first conductive layer 21 of the bus bar electrode portion 32 was measured at the stage of having formed the first conductive layer 21 in each of the solar cells of Examples 1 to 4 and Comparative Examples 1 to 3 described above. Further, the solar cell characteristics were measured using a solar simulator in each of the solar cells of Examples 1 to 4 and Comparative Examples 1 to 3 described above. After the measurement of the solar cell characteristics, in order to evaluate the bonding strength of the wiring member 3, a peeling test was performed and the appearance after the test was observed.

Since the bus bar electrode portion 32 is not provided in Example 3, the measurement of the line resistance of the first conductive layer 21 composing the bus bar electrode portion 32 was not performed. Further, the test for evaluating the bonding strength of the wiring member 3 was not performed in the modularized solar cells of Example 4 and Comparative Example 3.

Table 1 shows conditions for manufacturing the heterojunction solar cells of Examples 1 to 4 and Comparative Examples 1 to 3, results of the test for evaluating the bonding strength of the wiring member 3, and results of the measurement of the solar cell characteristics (fill factor (FF)) (represented by standardizing the results by defining the result of Example 1 as 1).

In Examples 1 to 3 and Comparative Examples 1 and 2, there was no superior-inferior difference in open-circuit voltage (Voc) and short circuit current density (Jsc) confirmed. Thus, description thereof in Table 1 is omitted.

TABLE 1

| | | | Line resistance of first | | |
|---|---|---|---|---|---|
| | Wiring member in | Width of bus bar | conductive layer of bus bar | Test of bonding strength of | |
| | plating | electrode portion | electrode portion | wiring member | FF |
| Example 1 | present | 1.5 mm | 0.5 Ω/cm | Cell breakage | 1 |
| Example 2 | present | 1.5 mm | 10 Ω/cm | Cell breakage | 1 |
| Example 3 | present | N/A | Not performed | Cell breakage | 1 |
| Example 4 | present | 1.5 mm | 0.5 Ω/cm | Not performed | — |
| Comparative | Absent | 1.5 mm | 0.5 Ω/cm | Peeling-off between first | 1 |
| example 1 | | | | conductive layer and second | |
| | | | | conductve layer | |
| Comparative | Absent | 1.5 mm | 10 Ω/cm | Peeling-off between first | 0.98 |
| example 2 | | | | conductive layer and second | |
| | | | | conductve layer | |
| Comparative | Absent | 1.5 mm | 0.5 Ω/cm | Not performed | — |
| example 3 | | | | | |

The results of the measurement of the bonding strength of the wiring member 3 in Comparative Examples 1 and 2 reveal that peeling-off occurs between the first conductive layer 21 and the second conductive layer 22. This shows that the bonding strength between the first conductive layer 21 and the second conductive layer 22 is weaker than the bonding strength in the other interfaces, and suggests that peeling-off is likely to occur between the first conductive layer 21 and the second conductive layer 22.

On the other hand, as can be seen from Table 1, the wiring member 3 is adhered to the solar cell 2 with a sufficiently strong strength in the solar cell 2 of the present invention.

Further, in Comparative Example 2 in which the line resistance of the first conductive layer 21 in the bus bar electrode 32 is 10 Ω/cm, a reduction in FF was confirmed. On the other hand, a reduction in FF did not occur in the present examples.

As described above using the examples, it is turned out that the present invention makes it possible to provide a solar cell having high reliability with simple steps as well as at a low cost.

### DESCRIPTION OF REFERENCE NUMERALS

1, 80 solar cell module
2, 81 solar cell
3 wiring member
5 front surface member (light transmissive member)
18 transparent electrode layer (front electrode layer)
21 first conductive layer
22 second conductive layer
23, 101 hole (opening)
28 rear electrode (rear electrode layer)
30 photoelectric conversion section
31 finger electrode
33 adhesive material (adhesive layer)

1. A solar cell module comprising:
a solar cell including a photoelectric conversion section and a collector electrode; and
a wiring member connecting the solar cell to an external circuit or another solar cell,
wherein the solar cell includes a finger electrode portion extending in a predetermined direction, the finger electrode portion being a region in which the collector electrode is disposed, in plan view of the photoelectric conversion section,
wherein the finger electrode portion has a stacked structure in which a first conductive layer and a second conductive layer are sequentially stacked on an outer side of the photoelectric conversion section with respect to the photoelectric conversion section,
wherein the second conductive layer is a layer different from the first conductive layer,
wherein the electrical resistance of the second conductive layer is equal to or lower than the electrical resistance of the first conductive layer,
wherein the wiring member is located on an outer side of the first conductive layer with respect to the photoelectric conversion section and arranged to intersect the finger electrode portion or an extension of the finger electrode portion, and
wherein an intersecting region between the finger electrode portion of the solar cell or the extension of the finger electrode portion thereof and the wiring member has a lamination structure of the following (1) or (2):
(1) a lamination structure in which the wiring member is in direct contact with the first conductive layer, and
(2) a lamination structure in which the first conductive layer and the wiring member are in contact with each other through an adhesive layer that differs from the second conductive layer interposed therebetween.

2. The solar cell module according to claim 1,
wherein the second conductive layer is a plating layer.

3. The solar cell module according to claim 1, further comprising a light transmissive member having a light transmissive property on an outer side of the wiring member with an outer direction with respect to the photoelectric conversion section,
wherein the solar cell is capable of collecting incident light into the photoelectric conversion section through the light transmissive member,
wherein the second conductive layer is stacked on a part of the outer surface or the entire outer surface of the wiring member with respect to the photoelectric conversion section in the intersecting region of the wiring member, and
wherein the surface roughness of the second conductive layer is larger than the surface roughness of the wiring member.

4. The solar cell module according to of claim 1, further comprising an insulation layer formed on an outer side of the photoelectric conversion section with respect to the photoelectric conversion section,
wherein the insulation layer has a light transmissive property.

5. The solar cell module according to of claim 1,
wherein the finger electrode portion includes an insulation layer interposed between the first conductive layer and the second conductive layer,
wherein the insulation layer has an opening, and
wherein the first conductive layer and the second conductive layer are electrically continuous with each other through the opening.

6. The solar cell module according to of claim 1, further comprising an insulation layer formed on an outer side of the photoelectric conversion section with respect to the photoelectric conversion section,
wherein the side surface of the intersecting region is coated with the insulation layer across the first conductive layer and the wiring member.

7. The solar cell module according to of claim 1, comprising a plurality of the solar cells,
wherein at least two of the plurality of the solar cells are connected to each other through the wiring member,
wherein each of the two solar cells includes a front electrode layer on the collector electrode side and a rear electrode layer on the side opposite to the collector electrode, the front electrode layer having positive voltage or negative voltage, the rear electrode layer having voltage opposite to the front electrode layer, and
wherein the wiring member electrically connects the front electrode layer of one of the two solar cells and the rear electrode layer of the other one of the two solar cells.

8. A method for producing a solar cell module including a solar cell having a photoelectric conversion section and a collector electrode, and a wiring member connecting the solar cell to an external circuit or another solar cell,
wherein the solar cell includes a finger electrode portion extending in a predetermined direction, the finger electrode portion being a region in which the collector electrode is disposed, in plan view of the photoelectric conversion section,
wherein the finger electrode portion has a stacked structure in which a first conductive layer and a second conductive layer are sequentially stacked on an outer side of the photoelectric conversion section with respect to the photoelectric conversion section,
wherein the second conductive layer is a layer different from the first conductive layer,
wherein the electrical resistance of the second conductive layer is equal to or lower than the electrical resistance of the first conductive layer,
wherein the wiring member is located on an outer side of the first conductive layer with respect to the photoelectric conversion section and arranged to intersect the finger electrode portion or an extension of the finger electrode portion, and
wherein an intersecting region between the finger electrode portion of the solar cell or the extension of the finger electrode portion thereof and the wiring member has a lamination structure of the following (1) or (2):
(1) a lamination structure in which the wiring member is in direct contact with the first conductive layer, and
(2) a lamination structure in which the first conductive layer and the wiring member are in contact with each other through an adhesive layer that differs from the second conductive layer interposed therebetween, the method comprising, with an outer direction defined with respect to the photoelectric conversion section:
a first conductive layer forming step of forming the first conductive layer on the outer side of the photoelectric conversion section;
a wiring member bonding step of connecting the wiring member to the outer side of the first conductive layer; and
a plating step of forming the second conductive layer on the outer side of the first conductive layer by a plating method, in this order.

9. A method for producing a solar cell module including a solar cell having a photoelectric conversion section and a collector electrode, and a wiring member connecting the solar cell to an external circuit or another solar cell,
wherein the solar cell includes a finger electrode portion extending in a predetermined direction, the finger electrode portion being a region in which the collector electrode is disposed, in plan view of the photoelectric conversion section,
wherein the finger electrode portion has a stacked structure in which a first conductive layer and a second conductive layer are sequentially stacked on an outer side of the photoelectric conversion section with respect to the photoelectric conversion section,
wherein the second conductive layer is a layer different from the first conductive layer,
wherein the electrical resistance of the second conductive layer is equal to or lower than the electrical resistance of the first conductive layer,
wherein the wiring member is located on an outer side of the first conductive layer with respect to the photoelectric conversion section and arranged to intersect the finger electrode portion or an extension of the finger electrode portion,
wherein an intersecting region between the finger electrode portion of the solar cell or the extension of the finger electrode portion thereof and the wiring member has a lamination structure of the following (1) or (2):
(1) a lamination structure in which the wiring member is in direct contact with the first conductive layer, and
(2) a lamination structure in which the first conductive layer and the wiring member are in contact with each other through an adhesive layer that differs from the second conductive layer interposed therebetween,
wherein the finger electrode portion includes an insulation layer interposed between the first conductive layer and the second conductive layer,
wherein the insulation layer has an opening, and
wherein the first conductive layer and the second conductive layer are electrically continuous with each other through the opening, the method comprising, with an outer direction defined with respect to the photoelectric conversion section:
a first conductive layer forming step of forming the first conductive layer on the outer side of the photoelectric conversion section;
a wiring member bonding step of connecting the wiring member to the outer side of the first conductive layer;
an insulation layer forming step of forming the insulation layer on the outer side of the first conductive layer, and
a plating step of forming the second conductive layer electrically continuous with the first conductive layer through the opening formed on the insulation layer by a plating method.

10. The method for producing the solar cell module according to claim 9,
wherein the first conductive layer forming step, the wiring member bonding step, the insulation layer forming step, and the plating step are performed in this order.

11. The method for producing the solar cell module according to of claim 8,
wherein the solar cell is immersed in a plating solution, and an electric power is supplied to the wiring member to form the second conductive layer in the plating step.

12. The method for producing the solar cell module according to claim 11,
wherein the power is supplied to a region in the wiring member, the region differing from a region bonded to the solar cell to form the second conductive layer.

13. The method for producing the solar cell module according to of claim 8, the solar cell module comprising a plurality of the solar cells,
wherein each of the solar cells is connected to each other by a wiring member, and
wherein an electric power is supplied to the wiring member to simultaneously form second conductive layers on the plurality of the solar cells.

14. The method for producing the solar cell module according to claim 9,
wherein the solar cell is immersed in a plating solution, and an electric power is supplied to the wiring member to form the second conductive layer in the plating step.

15. The method for producing the solar cell module according to claim 14,
wherein the power is supplied to a region in the wiring member, the region differing from a region bonded to the solar cell to form the second conductive layer.

16. The method for producing the solar cell module according to claim 9, the solar cell module comprising a plurality of the solar cells,
wherein each of the solar cells is connected to each other by a wiring member, and
an electric power is supplied to the wiring member to simultaneously form second conductive layers on the plurality of the solar cells.
